(19) United States
(12) Patent Application Publication
(10) Pub. No.: US 2009/0295838 A1
(43) Pub. Date: Dec. 3, 2009

(54) DA converter circuit, liquid crystal driver circuit, liquid crystal display apparatus, and method for designing DA converter circuit

(75) Inventor: Akira Tanigawa, Osaka (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 12/453,973

(22) Filed: May 28, 2009

(30) Foreign Application Priority Data
May 29, 2008 (JP) 2008-141018

(51) Int. Cl. G09G 5/10; H03M 1/76

(52) U.S. Cl. 345/690; 341/148; 345/89

(57) ABSTRACT

A DA converter circuit configured to output a gray scale voltage to a liquid crystal display panel is disclosed, wherein the gray scale voltage is generated from reference voltages fewer than gray scales of the liquid crystal display panel and it is still to be able to prevent deterioration in display quality of the liquid crystal display panel. A DA converter circuit of at least one embodiment includes: a reference voltage generator circuit for generating reference voltages; a selector circuit for selecting one or two reference voltages from the reference voltages in according to the inputted gray scale value; and a voltage follower circuit for outputting the gray scale voltage that is the one reference voltage thus selected or a mean value of the two reference voltages thus selected. Reference voltages are generated, in at least one embodiment, as a variety of gray scale voltages.

This Nonprovisional application claims priority under 35 U.S.C. §119(a) on Patent Application No. 2008-141018 filed in Japan on May 29, 2008, the entire contents of which are hereby incorporated by reference.

### TECHNICAL FIELD

The present invention relates to: a DA converter circuit included in a liquid crystal driver circuit for driving a liquid crystal display panel; a liquid crystal driver circuit including the DA converter circuit; a display apparatus including the liquid crystal driver circuit; and a method for designing the DA converter circuit.

### BACKGROUND ART

A liquid crystal driver circuit for driving a liquid crystal display panel includes a DA (digital-to-analogue) converter that converts, into a gray scale voltage which is an analogue signal, a gray scale value which is externally inputted as a digital signal. For example, a liquid crystal driver circuit included in an active matrix liquid crystal display apparatus drives a liquid crystal display panel in such a manner that a DA converter (i) converts, into a gray scale voltage, a gray scale value which has been externally inputted as a digital signal, and (ii) outputs the gray scale voltage to a source bus line of a liquid crystal display panel.

The following description deals with an example of an arrangement of a conventional DA converter used in a liquid crystal driver circuit, with reference to FIG. 11. FIG. 11 is a block diagram illustrating an arrangement of a conventional DA converter.

As illustrated in FIG. 11, a DA converter 100 includes a reference voltage generator circuit 101, a selector circuit 102, and a voltage follower circuit 103. FIG. 11 illustrates an example of an arrangement of a DA converter used in a 64-gray scale liquid crystal driver circuit. In accordance with 64 gray scale values indicated by 6-bit (Bit 5 to Bit 0) digital signals, the DA converter outputs 64 gray scale voltages.

Further, the reference voltage generator circuit 101 of the DA converter 100 includes 64 resistor elements connected in series. A maximum voltage value V₆₄ of a liquid crystal drive voltage is applied to one end terminal of a group of the 64 resistor elements, and a minimum voltage value V₀ of the liquid crystal drive voltage is applied to the other end terminal. This allows 64 reference voltages (V₀ through V₆₃) to be generated between the resistor elements, based on ratios corresponding to respective resistance values of the connected resistor elements. The 64 reference voltages generated by the reference voltage generator circuit 101 are inputted to the selector circuit 102.

In the selection circuit 102, a plurality of switches constituted by MOS transistors are arranged so that, in accordance with a gray scale value indicated by a 6-bit digital signal, one reference voltage is selected from the inputted 64 reference voltages, and then is outputted. In other words, in accordance with respective Bit 0 through Bit 5 of a 6-bit digital signal, that is, a gray scale value, the switches are turned on or off, so as to select one reference voltage from the inputted 64 reference voltages, and output the reference voltage. The following description deals with this operation more specifically.

That is, a gray scale value, which is a 6-bit digital signal, is such that Bit 5 is an MSB and Bit 0 is an LSB. The switches are arranged in pairs. There are 32 pairs of the switches (64 switches) at Bit 0. There are 16 pairs of the switches (32 switches) at Bit 1. Then, the number of the pairs decreases by half every Bit, and there is one pair of the switches (2 switches) at Bit 5. That is, the selector circuit 102 includes a total of “1+2+2²+2³+2⁴+2⁵=63” pairs of the switches (126 switches).

In FIG. 11, In a case where a corresponding Bit is “0”, a pair of the switches (2 switches) operates such that an upper switch is turned off, and a lower switch is turned on. On the other hand, in FIG. 11, in a case where a corresponding Bit is “1”, a pair of the switches operates such that, in FIG. 11, the upper switch is turned on, and the lower switch is turned off. For example, in the example illustrated in FIG. 11, “Bit 5, Bit 4, . . . Bit 0” are “111111”, so that all of the upper switches are turned on, and all of the lower switches are turned off. The selector circuit 102 outputs a reference voltage V₆₃ to the voltage follower circuit 103. Further, for example, if “Bit 5, Bit 4, . . . Bit 0” are “000001”, the selector circuit 102 outputs a reference voltage V₁ to the voltage follower circuit 103. The voltage follower circuit 103 outputs, to a source bus line of the liquid crystal display panel, a voltage equal to the reference voltage received from the selector circuit 102, as a gray scale voltage generated by a lower internal resistance.

In a case where the DA converter 100 is used as a liquid crystal driver circuit of a liquid crystal display apparatus, an increase in the number of displayed gray scales causes a significant increase in the number of elements constituting the liquid crystal driver circuit. For example, in a case of 64-gray scale display, first of all, it is necessary to provide 64 resistor elements in the reference voltage generator circuit 101. Further, it is also necessary to provide, for one source bus line, 126 switches constituting the selector circuit 102. In the same way, in a case where 256-gray scale display is carried out with gray scale values indicated by 8-bit digital signals, it is necessary to provide 256 resistor elements in the reference voltage generator circuit 101. Further, it is also necessary for the selector circuit 102 to include “1+2+2²+2³+ . . . +2⁷=255” pairs of the switches, that is, a total of 510 switches.

Furthermore, in a case of a liquid crystal display panel capable of carrying out color display, the liquid crystal display panel is driven such that one pixel is driven by three gray scale voltages corresponding to three colors. Accordingly, if N pixels are connected to one scan line in the liquid crystal display panel, the liquid crystal display panel includes 3×N source bus lines. Here, each source bus line requires one selector circuit 102. Therefore, in a case of the liquid crystal driver circuit for driving the liquid crystal display panel capable of carrying out color display, the total number of the switches included in the selector circuit 102 will be three times more than the number of the switches required for a liquid crystal display panel for carrying out black-and-white display.

Thus, if the number of colors displayed by the liquid crystal display apparatus including the liquid crystal driver circuit is increased, and the number of the gray scales used in the liquid crystal display apparatus is increased, there is a significant increase in the number of elements constituting the circuits of the liquid crystal driver circuit. As a result, in a case where the liquid crystal driver circuit is integrated, there is an increase in chip size of the liquid crystal driver circuit.

Patent Literature 1 discloses a DA converter illustrated in FIG. 12, which copes with such a significant increase in the number of the elements constituting the circuits of the liquid crystal driver circuit, caused along with an increase in the number of the gray scales used in the liquid crystal display apparatus. FIG. 12 is a block diagram illustrating a DA converter 200.

The DA converter 200 illustrated in FIG. 12 includes a reference voltage generator circuit 201, a selector circuit 202, and a voltage follower circuit 203. Like the example illustrated in FIG. 11, FIG. 12 illustrates an example of an arrangement of a DA converter used in a 64-gray scale liquid crystal driver circuit. In accordance with 64 gray scale values indicated by 6-bit (Bit 5 to Bit 0) digital signals, the DA converter outputs 64 gray scale voltages.

As illustrated in FIG. 12, the reference voltage generator circuit 201 is a voltage-dividing resistor circuit in which a plurality of resistor elements are connected to each other, and reference voltages are generated from connection sections between these resistor elements. The reference voltage generator circuit 201 includes 32 resistor elements connected in series. A maximum voltage value V₆₄ of the liquid crystal drive voltage is applied to one end terminal of a group of the 32 resistor elements, and a minimum voltage value V₀ of the liquid crystal drive voltage is applied to the other end terminal. This causes terminals of respective resistor elements to generate 33 reference voltages (V₀, V₂, V₄, V₆, . . . V₆₂, V₆₄) in accordance with ratios corresponding to resistance values of the respective resistor elements. There are intervals of one gray scale between the 33 reference voltages (voltages for driving the liquid crystal display panel).

In the selector circuit 202, a plurality of switches constituted by MOS transistors are arranged so that, in accordance with a gray scale value indicated by a 6-bit digital signal, two reference voltages are selected from the inputted 33 reference voltages, and then are outputted. In other words, in accordance with respective Bit 0 through Bit 5 of a 6-bit digital signal, that is, a gray scale value, the switches are turned on or off, so as to select two reference voltages from the inputted 33 reference voltages, and output the two reference voltages. Further, the voltage follower circuit 203 calculates a mean value of the two reference voltages selected by the selector circuit 202, and then outputs, to the source bus line of the liquid crystal display panel, the mean value as a gray scale voltage. The following description deals with this operation more specifically.

The switches included in the selector circuit 202 are arranged in pairs, so as to form switch pairs SW. A switch pair SW (0, 1) is provided at Bit 0, two switch pairs SW (1, 1) and SW (1, 2) are provided at Bit 1, three switch pairs SW (2, 1) through SW (2, 3) are provided at Bit 2, five switch pairs SW (3, 1) through SW (3, 5) are provided at Bit 3, nine switch pairs SW (4, 1) through SW (4, 9) are provided at Bit 4, and 17 switch pairs SW (5, 1) through SW (5, 17) are provided at Bit 5. That is, the selector circuit 202 includes a total of “1+2+(2¹+1)+(2²+1)+(2³+1)+(2⁴+1)=37” pairs SW of the switches (74 switches).

For example, in the example of FIG. 12, a gray scale values (Bit 5, Bit 4, . . . Bit 0) externally inputted is 111111, so that each of the switch pairs SW is such that an upper switch is turned on, and a lower switch is turned off. The selector circuit outputs a reference voltage V₆₄ to an input terminal IN2 of the voltage follower circuit 203, and outputs a reference voltage V₆₂ to an input terminal IN1 of the voltage follower circuit 203. Further, the voltage follower circuit 203 calculates a mean value of the outputted reference voltages V₆₄ and V₆₂, and outputs, to the source bus line of the liquid crystal display panel, the mean value V₆₃ as a gray scale voltage.

Moreover, in FIG. 12, for example, if the gray scale value (Bit 5, Bit 4, . . . Bit 0) externally inputted is “111110”, the switch pair SW (0, 1) is such that the upper switch is turned off, and the lower switch is turned on. In this case, each of the switch pairs SW, except the switch pair SW (0, 1), is such that the upper switch is turned on, and the lower switch is turned off. That is, both the input terminals IN2 and IN1 of the voltage follower circuit 203 receive the reference voltage V₆₂ from the selector circuit 202. Accordingly, the voltage follower circuit 203 outputs the gray scale voltage V₆₂ to the source bus line of the liquid crystal display panel.

As described above, the DA converter 200 can output gray scale voltages as many as gray scales indicated by gray scale values externally inputted. Here, it should be noted that the reference voltage generator circuit 201 only has to generate the reference voltages as many as nearly half of the gray scale voltages that the voltage follower circuit 203 outputs. Therefore, as compared with the reference voltage generator circuit illustrated in FIG. 11, it is possible to reduce the number of the reference voltages required to be generated. As a result, it becomes possible to reduce the number of the resistor elements included in the reference voltage generator circuit 201.

Further, the reduction in the number of the reference voltages that the reference voltage generator circuit 201 is required to generate allows a significant reduction in the number of the resistor elements included in the selector circuit 202, as compared with the selector circuit 102 illustrated in FIG. 11. For the reasons described above, in the DA converter 200, even if a bit count of a digital signal indicating a gray scale value is increased, it is possible to suppress a significant increase in the number of the elements (resistor elements and switches, for example) constituting the circuits. As a result, it becomes possible to suppress an increase in cost of manufacturing, and also to cause the apparatus to be smaller.

Furthermore, Patent Literature 2 discloses another DA converter in order to respond to a significant increase in the number of the elements constituting the circuits of the liquid crystal drive circuit, caused along with an increase in the number of the gray scales used in the liquid crystal display apparatus. Specifically, as compared with the DA converter disclosed in Patent Literature 1, the DA converter disclosed in Patent Literature 2 generates a gray scale voltage, which is to be outputted to the liquid crystal display panel, from reference voltages that is fewer than the gray scales of output gray scale voltages. Thereby, the DA converter disclosed in Patent Literature 2 allows the liquid crystal driver circuit including the DA converter to be smaller.

Citation List

Patent Literature 1

Japanese Patent Application Publication, Tokukai, No. 2000-183747 A (Publication Date: Jun. 30, 2000)

Patent Literature 2

Japanese Patent Application Publication, Tokukai, No. 2006-106771 A (Publication Date: Apr. 20, 2006)

### SUMMARY OF INVENTION

Technical Problem

However, the DA converters disclosed in Patent Literatures 1 and 2 have the following problems.

Firstly, in the liquid crystal display panel, a light transmittance does not always vary linearly with respect to a change in the gray scale voltage applied to the liquid crystal display panel. More specifically, a voltage range of the gray scale voltage includes a voltage range (hereinafter, referred to as a first voltage range) in which the light transmittance varies not-linearly with respect to a change in the gray scale voltage, and another voltage range (hereinafter, referred to as a second voltage range) in which the light transmittance varies linearly (substantially-linearly) with respect to a change in the gray scale voltage. Therefore, a driver circuit for driving the liquid crystal display panel is required to generate a gray scale voltage that has been gamma-corrected, in consideration of the gray scale voltage-light transmittance characteristic described above. It has been conventionally known that, in a voltage range that the gray scale voltage could take, the first voltage range is located at both end portions of the voltage range, and the second voltage range is located at a center portion of the voltage range.

Here, in a case where, like the DA converters disclosed in Patent Literatures 1 and 2, a gray scale voltage is generated such that (i) two reference voltages are selected from reference voltages that are fewer than the gray scales of the gray scale voltages, (ii) an average of the two reference voltages is calculated, or the two reference voltages are linear-interpolated, there will be a difference between the gray scale voltage generated in the first voltage range and an ideal gray scale voltage. This causes display quality of the liquid crystal display panel to be affected.

The following description deals with this problem more specifically with reference to FIG. 13 and FIG. 14. FIG. 13 and FIG. 14 illustrate a relationship between an ideal gray scale voltage corresponding to a gamma curve in an 8-gray scale DA converter, and a gray scale voltage (hereinafter, referred to as an output gray scale voltage) outputted from the DA converter. Further, FIG. 14 is a line graph showing the ideal gray scale voltage and the output gray scale voltage, both of which are shown in FIG. 13. The DA converter generates reference voltages corresponding to “0”, “2”, “4”, “6”, and “7”, among the gray scale values “0” through “7”. Accordingly, the DA converter generates gray scale voltages corresponding to the gray scale values “1”, “3”, and “5”, by calculating a mean value of two reference voltages corresponding to gray scale values adjacent to each other.

First, as illustrated in FIG. 13 and FIG. 14, at the gray scale values “2” through “6”, that is, at the center portion of the voltage range that a gray scale voltage could take, the ideal gray scale voltage varies linearly with respect to a change in the gray scale value. Therefore, there is no difference between the output gray scale voltage corresponding to the gray scale value “3” and the ideal gray scale voltage, and between the output gray scale voltage corresponding to the gray scale value “5” and the ideal gray scale voltage. However, the DA converter generates an output gray scale voltage 2.5V corresponding to a gray scale value “1” by calculating a mean value of a reference voltage 0V corresponding to a gray scale value “0” and a reference voltage 5V corresponding to a gray scale value “2”. As a result, there is a difference of 2V between the output gray scale voltage 2.5V corresponding to the gray scale value “1” and an ideal gray scale voltage 4.5V corresponding to the gray scale value “1”.

In view of the problem, the DA converter disclosed in Patent Literature 2 generates the reference voltages such that intervals of the reference voltages in the first voltage range are shorter than those in the second voltage range, as Shown in FIG. 15. This reduces a difference between the generated intermediate voltage and the ideal gray scale voltage. FIG. 15 is an explanatory view of the DA converter disclosed in Patent Literature 2, showing a correspondence between the reference voltages V₁ through V₈ and 64-gray scale voltages outputted from the DA converter.

However, in the DA converter disclosed in Patent Literature 2, even in the first voltage range, the linear interpolation is carried out between the reference voltages so as to generate an output gray scale voltage. Accordingly, it is impossible to eliminate the difference between the output gray scale voltage and the ideal gray scale voltage.

The present invention is made in view of the problem. An object of the present invention is to provide a DA converter circuit, a liquid crystal driver circuit including the DA converter circuit, a liquid crystal display apparatus including the liquid crystal driver circuit, and a method of designing the DA converter circuit, in each of which the DA converter circuit for outputting a gray scale voltage to a liquid crystal display panel (i) generates a gray scale voltage from reference voltages fewer than gray scales, and simultaneously (ii) prevents a reduction in display quality of the liquid crystal display panel.

Solution to Problem

A DA converter circuit according to the present invention is a DA converter circuit for outputting a gray scale voltage to a liquid crystal display panel in accordance with a gray scale value externally inputted to the DA converter circuit, where the gray scale voltage and the gray scale value are of n gray scales and n is a natural number of 2 or more. In order to attain the object, the DA converter circuit according to the present invention comprises: a generating section for generating m reference voltages, which are different from each other, where m is a natural number less than n; a selecting section for selecting one or two reference voltages from the m reference voltages in according to the inputted gray scale value; and an output section for outputting the gray scale voltage that is the one reference voltage thus selected or a mean value of the two reference voltages thus selected, the generating section generating the reference voltages in such a manner that, respectively for each end portion of a voltage range of the gray scale voltages of n gray scales, the generating section generates i reference voltages, where i is a natural number less than m and is as many as a variety of gray scale voltages that the output section is capable of outputting for each end portion respectively, and for a center portion of the voltage range, the generating section generates m−i reference voltages.

According to this configuration, the DA converter circuit outputs a gray scale voltage of n gray scales to the liquid crystal display panel in accordance with a gray scale value of n gray scales in such a manner that a selecting section selects one or two reference voltages from the m reference voltages in according to the inputted gray scale value, and output section outputs the gray scale voltage that is the one reference voltage thus selected or a mean value of the two reference voltages thus selected.

Therefore, it is not necessary that the generating section generate n reference voltages corresponding to n gray scales of the gray scale voltage one by one. It is sufficient that the generating section generates m reference voltages fewer than n reference voltages. This makes it possible to simplifies the generating section in terms of its circuit configuration, due to the reduction in the number of reference voltages to be generated. As a result, the DA converter circuit can have a smaller chip size, thereby leading to a smaller chip size of the liquid crystal driver circuit provided with this DA converter circuit.

Moreover, in the liquid crystal display panel, the light transmittance shows a non-linear change in each end portion of a voltage range of the applied gray scale voltage (hereinafter, the end portions of the voltage range is referred to as a first voltage range), meanwhile the light transmittance shows a linear (substantially linear) change in a center portion of the voltage range of the applied gray scale voltage (hereinafter, the center portion of the voltage range is referred to as a second voltage range).

Therefore, for the first voltage range (end portions of the voltage range of the gray scale voltage), the gray scale voltage to be outputted to the liquid crystal display panel should be subjected to gamma correction in consideration of the non-liner change of the light transmittance of the liquid crystal display panel. On the contrary, a conventional DA converter circuit outputs a mean value of two reference voltages as the gray scale voltage for the first voltage range. In this case, even gamma correction carried out on the reference voltages in advance will not eliminate a voltage difference between the outputted gray scale voltage and an ideal gray scale voltage, that is, cannot prevent a gap between the actual value and ideal value of the gray scale voltage, thereby deteriorating display quality of the liquid crystal display panel.

To solve this problem, the generating section of the DA converter circuit of the present invention is configured such that the generating section generating the reference voltages in such a manner that, respectively for each end portion of a voltage range of the gray scale voltages of n gray scales, the generating section generates i reference voltages, where i is a natural number less than m and is as many as a variety of gray scale voltages that the output section is capable of outputting for each end portion respectively, that is, for the first voltage range the generating section generates the reference voltages corresponding to the gray scale voltages one by one.

Therefore, the selector circuit can select one reference voltage solely corresponding to an inputted gray scale value in case the inputted gray scale value is a gray scale voltage for the first voltage range. Further, the gray scale voltage outputted from the output section can be the selected one reference voltage as such. As a result, the gray scale voltage outputted from the output section of the DA converter circuit according to the present invention for the first voltage range can be the reference voltage as such, which is generated by the generating section, but the output section of the DA converter circuit according to the present invention will not output a mean value of such reference voltages for the first voltage range. Thus, as long as the reference voltage is adjusted to the ideal gray scale voltage, a gray scale voltage equal to the ideal gray scale voltage can be outputted to the liquid crystal display panel. Consequently, the DA converter circuit according to the present invention can prevent the deterioration of the display quality of liquid crystal display panels.

With the configuration above, the DA converter circuit according to the present invention generates the gray scale voltages from the reference voltages fewer than the gray scales, but can prevent such deterioration of the display quality of the liquid crystal display panel.

Moreover, a liquid crystal driver circuit according to the present invention comprises the DA converter circuit as described above.

Furthermore, a liquid crystal display apparatus comprises the liquid crystal driver circuit as described above.

Moreover, a designing method according to the present invention is a method for designing the DA converter circuit as described above, and the method comprises: a first calculating step for calculating the gray scale voltage to be outputted from the output section, which gray scale voltage is the one reference voltage thus selected or the mean value of the two reference voltages thus selected; a second calculating step for calculating a difference between the mean value thus calculated and an ideal gray scale voltage value for a gray scale value corresponding to the mean value, the ideal gray scale value voltage being obtained in advance; and a voltage range determining step for determining the end portions and center portion of the voltage range according to the voltage difference thus calculated.

With this arrangement, voltage differences between mean values of pairs of reference voltages and an ideal gray scale voltage value for the gray scale value corresponding to the mean value is calculated, and a voltage range corresponding to mean values whose voltage differences with their corresponding ideal gray scale voltage values are out of a predetermined range is set as the voltage range of the end portion (the first voltage range), and a voltage range corresponding to mean values whose voltage differences with their corresponding ideal gray scale voltage values are within the predetermined range is set as the voltage range of the center portion (the second voltage range).

As described above, the DA converter circuit according to the present invention has such a circuit configuration that, for each end portion of the gray scale voltage range, reference voltages as many as gray scale voltages for the end portions are generated, and that, if a gray scale value corresponding to the end portions of the gray scale voltage range is inputted, a reference voltage corresponding to the gray scale value thus inputted is outputted.

Therefore, the DA converter circuit according to present invention is designed by the designing method according to the present invention so as to determine the voltage ranges of the end portions and center portion according to the voltage differences between the mean value of the reference voltages and the ideal gray scale voltage value. Such a DA converter circuit generates one reference voltage for one gray scale voltage for the first voltage range, and outputs the reference voltage as the gray scale voltage, instead of outputting a mean value of two reference voltages. Moreover, for the center portion of the voltage range, that is, for the second voltage range, a mean value of two reference voltage can be outputted as the gray scale voltage without the fear of causing the voltage difference between the gray scale voltage and the ideal gray scale voltage to be out of the predetermined range. That is, the DA converter circuit according to the present invention, which is designed by the designing method according to the present invention, can output gray scale voltage which is not deviated from the ideal gray scale voltage by a voltage difference greater than the predetermined range.

With this, the designing method according to the present invention for designing a DA converter circuit makes it possible to design a DA converter circuit that can generate gray scale voltages from reference voltages fewer than the number of gray scales and is still able to prevent deterioration of the display quality of a liquid crystal display panel.

Advantageous Effects of Invention

As described above, a DA converter circuit according to the present invention is a DA converter circuit for outputting a gray scale voltage to a liquid crystal display panel in accordance with a gray scale value externally inputted to the DA converter circuit, where the gray scale voltage and the gray scale value are of n gray scales and n is a natural number of 2 or more, and comprises: a generating section for generating m reference voltages, which are different from each other, where m is a natural number less than n; a selecting section for selecting one or two reference voltages from the m reference voltages in according to the inputted gray scale value; and an output section for outputting the gray scale voltage that is the one reference voltage thus selected or a mean value of the two reference voltages thus selected, the generating section generating the reference voltages in such a manner that, respectively for each end portion of a voltage range of the gray scale voltages of n gray scales, the generating section generates i reference voltages, where i is a natural number less than m and is as many as a variety of gray scale voltages that the output section is capable of outputting for each end portion respectively, and for a center portion of the voltage range, the generating section generates m−i reference voltages.

Therefore, the DA converter circuit according to the present invention can generate gray scale voltages from reference voltages fewer than the number of gray scales and is still able to prevent deterioration of the display quality of a liquid crystal display panel.

For a fuller understanding of the nature and advantages of the invention, reference should be made to the ensuing detailed description taken in conjunction with the accompanying drawings.

### BRIEF DESCRIPTION OF DRAWINGS

FIG. 1

FIG. 1 is a block diagram illustrating an arrangement of a DA converter circuit in accordance with an embodiment of the present invention.

FIG. 2

FIG. 2 is a block diagram illustrating an arrangement of the liquid crystal display apparatus in accordance with the embodiment of the present invention.

FIG. 3

FIG. 3 is a block diagram illustrating an arrangement of a source bus line driver circuit in accordance with the embodiment of the present invention.

FIG. 4

FIG. 4 is a block diagram illustrating an arrangement of the DA converter circuit in accordance with the embodiment of the present invention, in a case where a gray scale value “5” is inputted.

FIG. 5

FIG. 5 is a block diagram illustrating an arrangement of the DA converter circuit in accordance with the embodiment of the present invention, in a case where a gray scale value “17” is inputted.

FIG. 6

FIG. 6 is a view showing a relationship between an inputted gray scale value, an output of a selector circuit, and a gray scale voltage outputted from a voltage follower circuit, in the DA converter circuit in accordance with the embodiment of the present invention.

FIG. 7(a)

FIG. 7(a) is a chart showing an example of a relationship between a gray scale value inputted to the DA converter circuit in accordance with the embodiment of the present invention, and an ideal gray scale voltage that has been gamma-corrected.

FIG. 7(b)

FIG. 7(b) is a graph showing a relationship between the gray scale value and the gray scale voltage, both of which are shown in FIG. 7(a).

FIG. 8

FIG. 8 is an explanatory view showing a comparison between a gray scale voltage outputted from a DA converter circuit 43 in accordance with the embodiment of the present invention, a gray scale voltage outputted from a conventional DA converter 200, and an ideal gray scale voltage.

FIG. 9

FIG. 9 is a block diagram illustrating an arrangement of a DA converter circuit in accordance with another embodiment of the present invention.

FIG. 10

FIG. 10 is a block diagram illustrating an arrangement of a DA converter circuit in accordance with further another embodiment of the present invention.

FIG. 11

FIG. 11 is a block diagram illustrating an arrangement of a conventional DA converter.

FIG. 12

FIG. 12 is a block diagram illustrating an arrangement of another conventional DA converter.

FIG. 13

FIG. 13 is a view showing a relationship between a gray scale voltage outputted from a DA converter of the another conventional example, and an ideal gray scale voltage that has been gamma-corrected.

FIG. 14

FIG. 14 is a line graph showing a relationship between a gray scale voltage outputted from the DA converter of the another conventional example and the ideal gray scale voltage that has been gamma-corrected.

FIG. 15

FIG. 15 is a view showing a relationship between a reference voltage and a gray scale voltage, in further another conventional DA converter.

### DESCRIPTION OF EMBODIMENTS

One embodiment of the present invention is described below with reference to the attached drawings.

### Embodiment 1

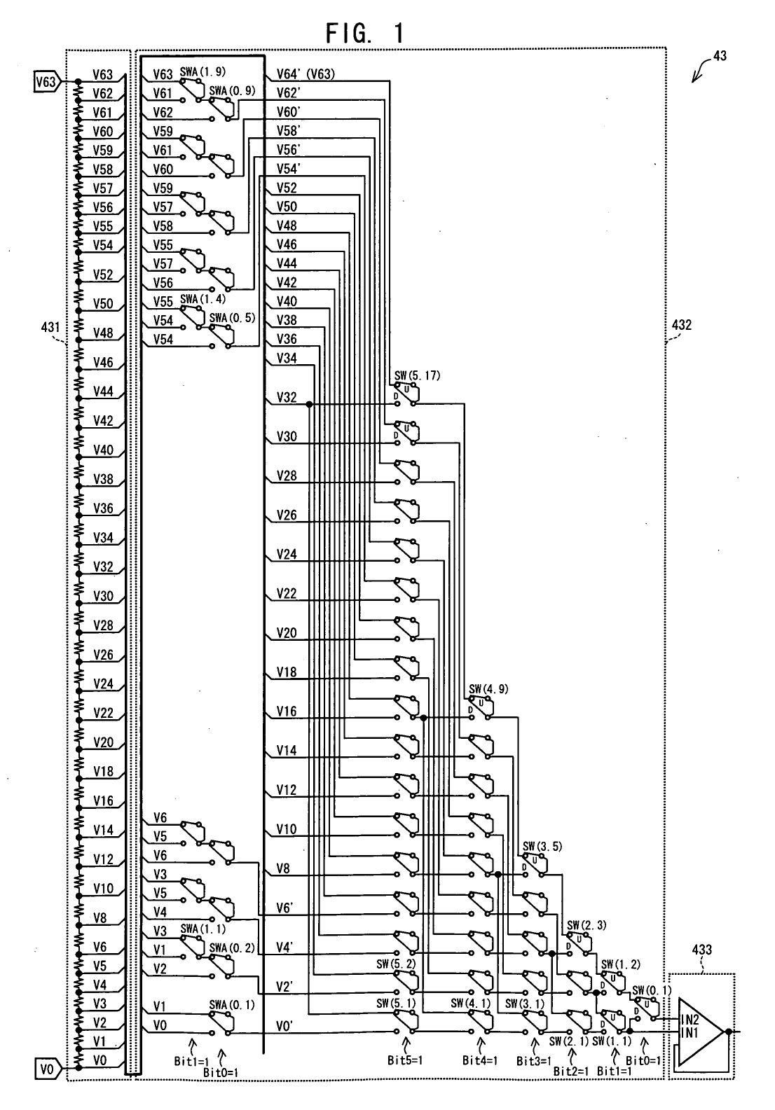

The following explains Embodiment 1 of the present invention with reference to FIGS. 1 through 8.

(Configuration of Liquid Crystal Display Apparatus 10)

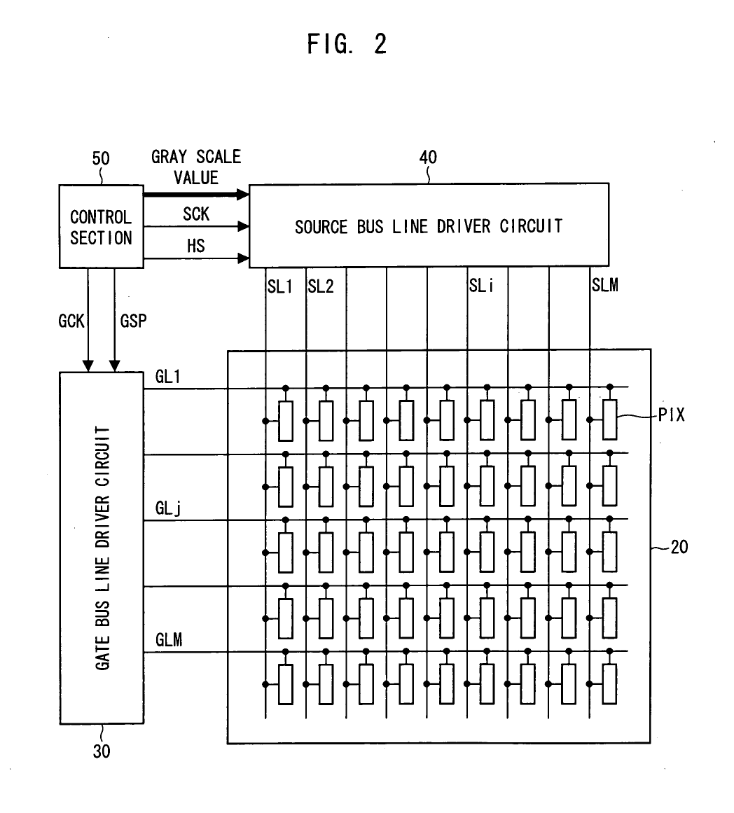

First, with reference to FIG. 2, a configuration of a liquid crystal display apparatus 10 of the present invention is explained below. FIG. 2 is a block diagram illustrating the configuration of the TFT (Thin Film Transistor) liquid crystal display apparatus 10 that is a typical example of an active matrix liquid crystal display apparatus.

As shown in FIG. 2, the liquid crystal display apparatus 10 includes a liquid crystal display panel 20, a gate bus line driver circuit 30, a source bus line driver circuit 40, and a control section 50.

Though not specifically illustrated, the liquid crystal display panel 20 is made of two transparent substrates, between which liquid crystals are filled. The two transparent substrates are a matrix substrate and a counter substrate that includes a counter electrode. These two transparent substrates are arranged in parallel so as to face each other and a predetermined space is provided between these two transparent substrates.

The matrix substrate is provided with (i) a plurality of (M, in the present embodiment) source bus lines SLi(i=1 to M) that are parallel to each other and (ii) a plurality of (N, in the present embodiment) gate bus lines GLj(j=1 to N) that are parallel to each other and intersect with the source bus lines SLi. A pixel PIXij is provided in each section surrounded by adjacent two gate bus lines GLj and GL(j+1) and two adjacent source bus lines SLi and SL(i+1).

The gate bus line driver circuit 30 is provided for outputting (i) a high-level voltage to a gate bus line GLj that is selected from the plurality of gate bus lines GLj(j=1 to N) provided in the liquid crystal display panel 20 and (ii) a low-level voltage to other gate bus lines GLj (gate bus lines GLj other than the gate bus line GLj selected).

(Operation of Liquid Crystal Display Apparatus 10)

As shown in FIG. 2, the control section 50 outputs a gate clock signal GCK and a gate start pulse signal GSP to the gate bus line driver circuit 30. The gate bus line driver circuit 30 outputs a high-level voltage to the gate bus lines GLj by turns in order from the gate bus line GL1, at a timing indicated by the gate start pulse signal GSP. The gate start pulse signal GSP corresponds to a period of the gate clock signal GCK. In other words, on the assumption that the output voltage with respect to the gate bus line GLj is GDOUTj, the gate bus line driver circuit 30 switches GDOUT1 from a low level to a high level, at a timing indicated by the gate start pulse signal GSP. Next, in accordance with the period of the gate clock signal GCK, the gate bus line driver circuit 30 switches GDOUT1 back to the low level, and also switches GDOUT2 from a low level to a high level. Thereafter, in the same manner, the gate bus line driver circuit 30 switches GDOUTj by turns, from a low level to a high level and then back to the low level. That is, the gate bus line driver circuit 30 selects one gate bus line and outputs a high-level signal to the gate bus line so as to select, by a gate bus line unit, each pixel to which a gray scale voltage is to be outputted from the source bus line driver circuit 40.

(Configuration and Operation of Source Bus Line Driver Circuit 40)

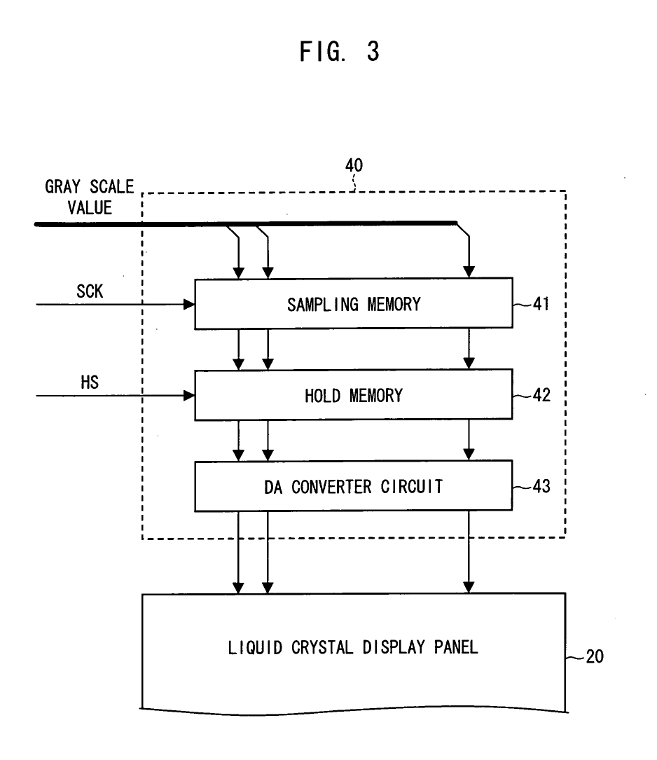

Next, a configuration and an operation of the source bus line driver circuit 40 (liquid crystal driver circuit) are explained below with reference to FIG. 3. FIG. 3 is a block diagram illustrating the configuration of the source bus line driver circuit 40.

As shown in FIG. 3, the source bus line driver circuit 40 includes a sampling memory 41, a hold memory 42, and a DA converter circuit 43.

The source bus line driver circuit 40 outputs a gray scale voltage to each of pixels PIX1j to PIXMj via each source bus line SLi(i=1 to M). The gray scale voltage corresponds to each pixel PIXj that is selected by the gate bus line driver circuit 30 and connected to the gate bus line GLj. For specifically explaining the operation of the source bus line driver circuit 40, the following explains, as an example, a case where the source bus line driver circuit 40 outputs each gray scale value to each of the pixels PIX1j to PIXMj that are connected to a gate bus line GLj.

The control section 50 inputs a clock signal SCK and each gray scale value made of a digital signal into the source bus line driver circuit 40. In the source bus line driver circuit 40, the sampling memory 41 inside the source bus line driver circuit 40 is supplied with each gray scale value that is for one horizontal scanning period in synchronism with the clock signal SCK, and corresponds to each of the pixels PIX1j to PIXMj. This sampling memory 41 includes data storage areas of the same number (i.e., M) as the number of the source bus lines SL, and stores gray scale values each corresponding to each source bus line SL in the respective data storage areas.

Then, in the source bus line driver circuit 40, each gray scale value (for each of the pixels PIX1j to PIXMj) that is for one horizontal scanning period and stored by the sampling memory 41 is transferred at a timing of a horizontal sync signal HS to the hold memory 42 in a subsequent stage. This hold memory 42 also includes data storage areas of the same number (i.e., M) as the number of the source bus lines SL, and stores gray scale values each corresponding to each source bus line SL in the respective data storage areas.

Further, the hold memory 42 outputs the transferred gray scale values to the DA converter circuit 43 in a subsequent stage as well as temporality storing the transferred gray scale values in the respective data storage areas inside the hold memory 42. The DA converter circuit 43 converts, into gray scale voltages that are analog voltages, the gray scale values that are digital signals outputted from the hold memory 42. Then, the DA converter circuit 43 outputs the gray scale voltages to the respective source bus lines SL1 to SLM included in the liquid crystal display panel 20.

The control section 50 controls and outputs the horizontal sync signal HS, the gate clock signal GCK, and the gate start pulse signal GSP so that the horizontal sync signal HS, the gate clock signal GCK, and the gate start pulse signal GSP are outputted at timings corresponding to one other. Accordingly, the gray scale voltages each outputted from the source bus line driver circuit 40 and corresponding to each of the pixels PIX1j to PIXMj are outputted, via the source bus lines SL1 to SLM, to the corresponding pixels PIX1j to PIXMj connected to a gate bus line SLj selected by the gate bus line driver circuit 30.

(Configuration of DA Converter Circuit 43)

Next, the DA converter circuit 43 of the present embodiment is explained below with reference to FIGS. 1 and 4 through 8. First, with reference to FIG. 1, a configuration of the DA converter circuit 43 is explained. Note that FIG. 1 illustrates, as an example, the DA converter circuit 43 that converts a 6-bit gray scale value (gray scale value in a range of “0” to “63”) into a gray scale voltage of 64 gray scales.

As shown in FIG. 1, the DA converter circuit 43 includes a reference voltage generator circuit 431 (generating section), a selector circuit 432 (selecting section), and a voltage follower circuit 433 (output section).

(Configuration and Operation of Reference Voltage Generator Circuit 431)

The reference voltage generator circuit 431 is a resistor divider circuit in which a plurality of resistor elements are connected in series and a reference voltage is derived from each connecting section between the resistor elements. The reference voltage generator circuit 431 is configured by connecting 39 resistor elements in series. One end of the reference voltage generator circuit 431 is supplied with an input of a maximum value (V₆₃) of gray scale voltages, and the other end of the reference voltage generator circuit 431 is supplied with an input of a minimum value (V₀) of the gray scale voltages. This allows the reference voltage generator circuit 431 to generate 40 kinds of reference voltages from respective terminals of the resistor elements. Each of the reference voltages is generated at a rate in accordance with each resistor value of each of the resistor elements.

The reference voltage generator circuit 431 here generates 16 kinds of reference voltages in a voltage range of gray scale voltages (V₀ to V₅ and V₅₄ to V₆₃: hereinafter, referred to as a first voltage range) corresponding to gray scale values of “0” to “5” and “54” to “63”, in other words, in both end portions of a voltage range of possible gray scale voltages of the 64 gray scales. The number 16 is equal to the number of the gray scale voltages. The reference voltage generator circuit 431 also generates 24 kinds of reference voltages in a voltage range of gray scale voltages (V₆ to V₅₃: hereinafter, referred to as a second voltage range) corresponding to gray scale values of “6” to “53”, in other words, in a center portion of the voltage range of the possible gray scale voltages of the 64 gray scales. The number 24 is a half of the number of the gray scale voltages. That is, the reference voltage generator circuit 431 generates reference voltages each corresponding to one corresponding gray scale voltage in the first voltage range, while generating reference voltages corresponding to every two gray scale voltages in the second voltage range. The reference voltage generator circuit 431 outputs thus generated 40 kinds of reference voltages to the selector circuit 432. Note that a resistor value of each resistor element included in the reference voltage generator circuit 431 is preset so that a voltage value of each reference voltage to be generated becomes an ideal gray scale voltage. In the example shown in FIG. 1, the reference voltage generator circuit 431 generates the voltages V₀ to V₆ and V₅₄ to V₆₃ as reference voltages corresponding to the gray scale values “0” to “6” and “54” to “63”, respectively, and the voltages V₈, V₁₀, . . . , V₄₈, V₅₀, and V₅₂ as reference voltages corresponding to the gray scale values “8”, “10”, . . . , “48”, “50” and “52”, respectively. Each of these reference voltages to be generated are set in a production process of the DA converter circuit or the like so that each reference voltage becomes identical to an ideal gray scale voltage of a corresponding gray scale value.

(Configuration and Operation of Selector Circuit 432)

The selector circuit 432 selects one or two reference voltages from the 40 kinds of reference voltages outputted from the reference voltage generator circuit 431 and outputs the one or two corresponding reference voltages, according to a 6-bit gray scale value. The selector circuit 432 can be configured by, for example, analog switches such as MOS transistors or transmission gates. Each of the above switches is configured as a switch pair made of two switches. Each of the above switches selects and outputs one of two input signals, according to the 6-bit gray scale value.

In FIG. 1, each of the switch pairs is represented as SW (X, Y) or SWA (X, Y). Here, X corresponds to the number (0, 1, 2, . . . , and 5) of a bit of a gray scale value. Y represents a position in a vertical direction of FIG. 1 and is given the number 1, 2, . . . , in order from the bottom of FIG. 1. Between the two switches that constitute one switch pair, an upper switch is designated as U and a lower switch is designated as D in FIG. 1 so that the upper and lower switches are distinguished. For example, SW (5, 3) represents a switch pair that operates according to Bit 5 (MSB) of a 6-bit gray scale value and that is provided in the third position from the bottom of FIG. 1. Further, in this switch pair, an upper switch is represented as SW (5, 3) U and a lower switch is represented as SW (5, 3) D.

In FIG. 1, in a case where switch pairs aligned vertically is collectively represented, in other words, in a case where switch pairs that operate according to the same bit number of respective gray scale values are collectively represented, the number corresponding to Y is omitted in a representation. For example, though switch pairs that operate according to Bit 5 of respective gray scale values are represented as SW (5, 1), SW (5, 2), . . . , the switch pairs are collectively represented as SW (5). Further, the number corresponding to Y is omitted in a representation for collectively representing upper switches of all switch pairs that operate according to the same predetermined bit number of respective gray scale values. For example, though upper switches of switch pairs that operate according to Bit 4 of respective gray scale values are represented as SW (4, 1) U, SW (4, 2) U, . . . , these upper switches are collectively referred to as SW (4) U. The same applies to the lower switches. The representation for collectively representing the switch pairs SW (X, Y) as described above also applies to the switch pairs SWA (X, Y). Further, the switch pairs SW (0), SW (1), . . . , and SW (5) included in the selector circuit 432 are collectively referred to as SW, and the switch pairs SWA (0) and SWA (1) are collectively referred to as SWA.

(Positional Relation of Switches)

Next, the following explains a positional relation of switches in each bit of the gray scale values. Switch pairs that operate according to Bit 5 (MSB) of respective 6-bit gray scale values are 17 switch pairs that include SW (5, 1) to SW (5, 17). Each of the switch pairs is made of two switches U and D.

V₀′ from a common terminal of SWA (0, 1) is inputted into one end of SW (5, 1) D and V₃₂ is inputted into one end of SW (5, 1) U. The other ends of SW (5, 1) U and SW (5, 1) D are connected to each other and form a common terminal. The same applies to SW (5, 2) to SW (5, 4). That is, V₂₍ₙ₋₁₎′ from a common terminal of SWA (0, n) is inputted into one end of SW (5, n) D and V₂₍ₙ₋₁₎₊₃₂ is inputted into one end of SW (5, n) U. Further, the other ends of these SW (5, n) D and SW (5, n) U are connected to each other and form a common terminal. Here, n=1, 2, 3, and 4. Note that, in FIG. 1: V₀′ indicates a reference voltage that is of V₀ or V₁ and selected by SWA (0, 1); V₂′ indicates a reference voltage that is of one of V₁, V₂, and V₃ and selected by SWA (1, 1) and SWA (0, 2); V₄′ indicates a reference voltage that is of one of V₃, V₄, and V₅ and selected by SWA (1, 2) and SWA (0, 3); and V₆′ indicates a reference voltage that is of V₅ or V₆ and selected by SWA (1, 3) and SWA (0, 4).

Further, V₈ is inputted into one end of SW (5, 5) D and V₄₀ is inputted into one end of SW (5, 5) U. Moreover, the other ends of SW (5, 5) U and SW (5, 5) D are connected to each other and form a common terminal. The same applies to SW (5, 6) to SW (5, 11). That is, V₂₍ₘ₋₁₎ is inputted into one end of SW (5, m) D and V₂₍ₘ₋₁₎₊₃₂ is inputted into one end of SW (5, m) U. Moreover, the other ends of SW (5, m) U and SW (5, m) D are connected to each other and form a common terminal. Here, m=5, 6, . . . , and 11.

Further, V₂₂ is inputted into one end of SW (5, 12) D and V₅₄′ from a common terminal of SWA (0, 5) is inputted into one end of SW (5, 12) U. The other ends of SW (5, 12) U and SW (5, 12) D are connected to each other and form a common terminal. The same applies to SW (5, 13) to SW (5, 17). That is, V₂₍ₖ₋₁₎ is inputted into one end of SW (5, k) D and V₂₍ₖ₋₁₎₊₃₂′ from a common terminal of SWA (0, k−7) is inputted into one end of SW (5, k) U. Moreover, the other ends of SW (5, k) U and SW (5, k) D are connected to each other and form a common terminal. Here, k=12, 13, . . . , and 17. Note that, in FIG. 1: V₅₄′ indicates a reference voltage that is of V₅₄ or V₅₅ and selected by SWA (1, 4) and SWA (0, 5); V₅₆′ indicates a reference voltage that is of one of V₅₅, V₅₆, and V₅₇ and selected by SWA (1, 5) and SWA (0, 6); V₅₈′ indicates a reference voltage that is of one of V₅₇, V₅₈, and V₅₉ and selected by SWA (1, 6) and SWA (0, 7); V₆₀′ indicates a reference voltage that is of one of V₅₉, V₆₀, and V₆₁ and selected by SWA (1, 7) and SWA (0, 8); V₆₂′ indicates a reference voltage that is of one of V₆₁, V₆₂, and V₆₃ and selected by SWA (1, 8) and SWA (0, 9); and V₆₄′ indicates a reference voltage of V₆₃.

These switch pairs SW (5) work in line with one another. When Bit 5 of the gray scale values is “0”, the lower switches SW (5) D are turned ON, but the upper switches SW (5) U are turned OFF. On the other hand, when Bit 5 of the gray scale values is “1”, the lower switches SW (5) D are turned OFF, but the upper switches SW (5) U are turned ON.

Switch pairs that operate according to Bit 4 are 9 switch pairs that include SW (4, 1) to SW (4, 9). In the same manner as described above, each switch is made of two switches U and D.

The common terminal of SW (5, 1) is connected to one end of SW (4, 1) D and the common terminal of SW (5, 9) is connected to one end of SW (4, 1) U. Moreover, the other ends of SW (4, 1) D and SW (4, 1) U are connected to each other and form a common terminal. In the same manner, the common terminal of SW (5, j) is connected to one end of SW (4, j) D and the common terminal of SW (5, j+8) is connected to one end of SW (4, j) U. The other ends of SW (4, j) D and SW (4, j) U are connected to each other and form a common terminal. Here, j=1, 2, . . . , and 9.

These switch pairs SW (4) work in line with one another. When Bit 4 is “0”, the lower switches SW (4) D are turned ON, but the upper switches SW (4) U are turned OFF. On the other hand, when Bit 4 is “1”, the lower switches SW (4) D are turned OFF, but the upper switches SW (4) U are turned ON.

Switch pairs that operate according to Bit 3 are 5 switch pairs that include SW (3, 1) to SW (3, 5). In the same manner as described above, each switch is made of two switches U and D.

The common terminal of SW (4, 1) is connected to one end of SW (3, 1) D and the common terminal of SW (4, 5) is connected to one end of SW (3, 1) U. Moreover, the other ends of SW (3, 1) D and SW (3, 1) U are connected to each other and form a common terminal. In the same manner, the common terminal of SW (4, i) is connected to one end of SW (3, i) D and the common terminal of SW (4, i+4) is connected to one end of SW (3, i) U. The other ends of SW (3, i) D and SW (3, i) U are connected to each other and form a common terminal. Here, i=1, 2, . . . , and 5.

These switch pairs SW (3) work in line with one another. When Bit 3 is “0”, the lower switches SW (3) D are turned ON, but the upper switches SW (3) U are turned OFF. On the other hand, when Bit 3 is “1”, the lower switches SW (3) D are turned OFF, but the upper switches SW (3) U are turned ON.

Switch pairs that operate according to Bit 2 are 3 switch pairs that include SW (2, 1) to SW (2, 3). In the same manner as described above, each switch is made of two switches U and D.

The common terminal of SW (3, 1) is connected to one end of SW (2, 1) D and the common terminal of SW (3, 3) is connected to one end of SW (2, 1) U. Moreover, the other ends of SW (2, 1) D and SW (2, 1) U are connected to each other and form a common terminal. In the same manner, the common terminal of SW (3, h) is connected to one end of SW (2, h) D and the common terminal of SW (3, h+2) is connected to one end of SW (2, h) U. The other ends of SW (2, h) D and SW (2, h) U are connected to each other and form a common terminal. Here, h=1, 2, and 3.

These switch pairs SW (2) work in line with one another. When Bit 2 is “0”, the lower switches SW (2) D are turned ON, but the upper switches SW (2) U are turned OFF. On the other hand, when Bit 2 is “1”, the lower switches SW (2) D are turned OFF, but the upper switches SW (2) U are turned ON.

Switch pairs that operate according to Bit 1 are two switch pairs SW (1, 1) and SW (1, 2) and 8 switch pairs SWA (1, 1) to SWA (1, 8). In the same manner as described above, each switch is made of two switches U and D.

The common terminal of SW (2, 1) is connected to one end of SW (1, 1) D and the common terminal of SW (2, 2) is connected to one end of SW (1, 1) U. Moreover, the other ends of SW (1, 1) D and SW (1, 1) U are connected to each other and form a common terminal. The common terminal of SW (2, 2) is connected to one end of SW (1, 2) D and the common terminal of SW (2, 3) is connected to one end of SW (1, 2) U. The other ends of SW (1, 2) D and SW (1, 2) U are connected to each other and form a common terminal.

These switch pairs SW (1) work in line with each another. When Bit 1 is “0”, the lower switches SW (1) D are turned ON, but the upper switches SW (1) U are turned OFF. On the other hand, when Bit 1 is “1”, the lower switches SW (1) D are turned OFF, but the upper switches SW (1) U are turned ON.

Further, V₁ is inputted into one end of SWA (1, 1) D and V₃ is inputted into one end of SWA (1, 1) U. V₅ is inputted into one end of SWA (1, 2) D and V₃ is inputted into one end of SWA (1, 2) U. V₅ is inputted into one end of SWA (1, 3) D and V₆ is inputted into one end of SWA (1, 3) U. V₅₄ is inputted into one end of SWA (1, 4) D and V₅₅ is inputted into one end of SWA (1, 4) U. V₅₅ is inputted into one end of SWA (1, 5) D and V₅₇ is inputted into one end of SWA (1, 5) U. V₅₇ is inputted into one end of SWA (1, 6) D and V₅₉ is inputted into one end of SWA (1, 6) U. V₆₁ is inputted into one end of SWA (1, 7) D and V₅₉ is inputted into one end of SWA (1, 7) U. V₆₁ is inputted into one end of SWA (1, 8) D and V₆₃ is inputted into one end of SWA (1, 8) U. The other ends of SWA (1) U and SWA (1) D are connected to each other and form each common terminal.

These switch pairs SWA (1) work in line with one another. When Bit 1 is “0”, the lower switches SWA (1) D are turned ON, but the upper switches SWA (1) U are turned OFF. On the other hand, when Bit 1, the lower switches SWA (1) D are turned OFF, but the upper switches SWA (1) U are turned ON.

Switch pairs that operate according to Bit 0 are one switch pair SW (0, 1) and nine switch pairs SWA (0, 1) to SWA (0, 9). In the same manner as described above, each switch is made of two switches U and D.

The common terminal of SW (1, 1) is connected to one end of SW (0, 1) D and the common terminal of SW (1, 2) is connected to one end of SW (0, 1) U. Moreover, the other ends of SW (0, 1) D and SW (0, 1) U are connected to each other and form a common terminal. This common terminal is further connected to an input terminal IN2 of the voltage follower circuit 433. The common terminal of SW (1, 1) is connected to an input terminal IN1 of the voltage follower circuit 433 as well as being connected to the one end of SW (0, 1) D as described above.

Further, V₀ is inputted into one end of SWA (0, 1) D and V₁ is inputted into one end of SWA (0, 1) U. V₂ is inputted into one end of SWA (0, 2) D and the common terminal of SWA (1, 1) is connected to one end of SWA (0, 2) U. V₄ is inputted into one end of SWA (0, 3) D and the common terminal of SWA (1, 2) is connected to one end of SWA (0, 3) U. V₆ is inputted into one end of SWA (0, 4) D and the common terminal of SWA (1, 3) is connected to one end of SWA (0, 4) U.

Furthermore, V₅₄ is inputted into one end of SWA (0, 5) D and the common terminal of SWA (1, 4) is connected to one end of SWA (0, 5) U. The other terminals of SW (0, 5) D and SW (0, 5) U are connected to each other and form a common terminal. The same applies to SWA (0, 6) to SWA (0, 9). V_{2g+44} is inputted into one end of SWA (0, g) D and the common terminal of SWA (1, g−1) is connected to one end of SWA (0, g) U. Here, g=6, 7, 8, and 9. The other terminals of SWA (0) D and SWA (0) U are connected to each other and form each common terminal.

As described above, in the selector circuit 432, the switch pairs SW and the switch pairs SWA operate according to a 6-bit gray scale value that the control section (See FIG. 2) 50 inputs into the switch pairs SW and SWA. Consequently, the selector circuit 432 selects two reference voltages corresponding to the gray scale value from 40 kinds of reference voltages that are generated by the reference voltage generator circuit 431, and outputs thus selected reference voltages to the voltage follower circuit 433.

As described above, the selector circuit 432 selects two reference voltages. In a case where two equal reference voltages are selected, the reference voltages may be represented as one reference voltage.

(Configuration and Operation of Voltage Follower Circuit 433)

Next, a configuration and an operation of the voltage follower circuit 433 are explained. The two reference voltages having been selected by the selector circuit 432 are inputted into the voltage follower circuit 433 via the input terminal IN1 and IN2, respectively. Note that, in the following explanation, the reference voltage to be inputted into the input terminal IN1 is represented as V_{IN1} and the reference voltage to be inputted into the input terminal IN2 is represented as V_{IN2}.

The voltage follower circuit 433 averages V_{IN1} and V_{IN2} inputted therein and outputs thus obtained mean voltage as a gray scale voltage V_{OUT} to the source bus line SL (See FIG. 2) included in the liquid crystal display panel 20.

Therefore, in a case where the reference voltages of the same voltage value are inputted into the input terminal IN1 and the input terminal IN2, respectively, that is, in the case of V_{IN1}=V_{IN2}, the voltage follower circuit 433 outputs thus supplied V_{IN1} (V_{IN2}) as V_{OUT}. On the other hand, in a case where the different reference voltages are inputted into the input terminal IN1 and the input terminal IN2, respectively, the voltage follower circuit 433 outputs (V_{IN1}+V_{IN2})/2 as V_{OUT}.

The voltage follower circuit 433 of the present embodiment is described in detail in Patent Literature 1 (Japanese Patent Application Publication, Tokukai, No. 2000-183747).

### SPECIFIC EXAMPLE 1

According to the example illustrated in FIG. 1, a gray scale value “63” which causes a bit sequence to be “111111” is inputted, and all upper switches (in FIG. 1) of the switch pairs SW and SWA are turned on and all lower switches (in FIG. 1) of the switch pairs SW and SWA are turned off. Thus, the selector circuit 432 outputs reference voltages, each of which has a voltage value of V₆₃, respectively to the input terminals IN1 and IN2 of the voltage follower circuit 433. The voltage follower circuit 433 outputs, as a gray scale voltage Vₒᵤₜ, a voltage value obtained by averaging V₆₃ inputted to the input terminal IN1 and V₆₃ inputted to the input terminal IN2, since the same voltage value V₆₃ is inputted to both the input terminals.

### SPECIFIC EXAMPLE 2

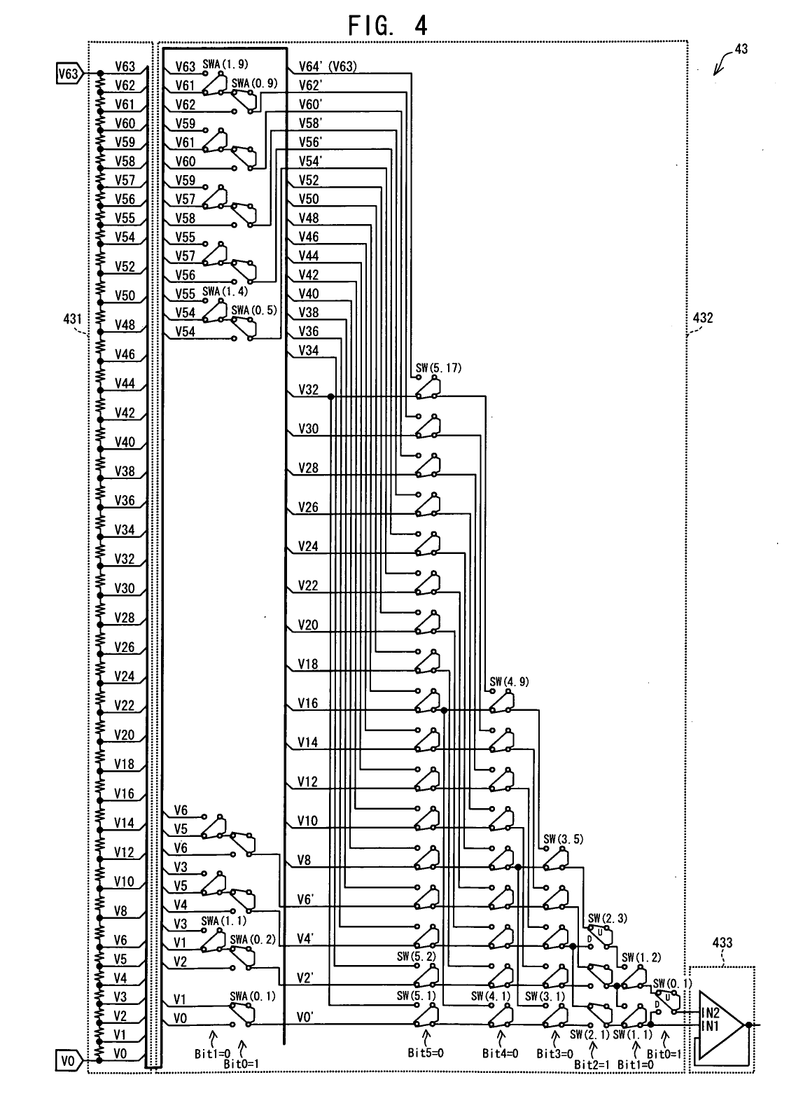

With reference to FIG. 4, the following describes how the DA converter circuit 43 operates in case where another gray scale value is inputted from the control section 50. FIG. 4 is an explanatory drawing explaining how the DA converter circuit 43 operates in case where a gray scale value “5” which causes the bit sequence to be “000101” is inputted.

As illustrated in FIG. 4, in case where the gray scale value “5” which causes the bit sequence to be “000101” is inputted, switch pairs SW(0)U, SW(2)U, and SWA(0)U are turned on in the selector circuit 432, and adversely switch pairs SW(0)D, SW(2)D, and SWA(0)D are turned off in the selector circuit 432. Further, switch pairs SW(5)U, SW(4)U, SW(3)U, SW(1)U, and SWA(1)U are turned off, and adversely switch pairs SW(5)D, SW(4)D, SW(3)D, SW(1)D, and SWA(1)D are turned on. Thus, the selector circuit 432 outputs reference voltages, each of which has a voltage value of V₅, to respectively the input terminals IN1 and IN2 of the voltage follower circuit 433. The voltage follower circuit 433 outputs the inputted V₅ as a gray scale voltage Vₒᵤₜ since a voltage value obtained by averaging V₅ inputted to the input terminal IN1 and V₅ inputted to the input terminal IN2, herein, the same voltage value V₅ is inputted to both the input terminals.

### SPECIFIC EXAMPLE 3

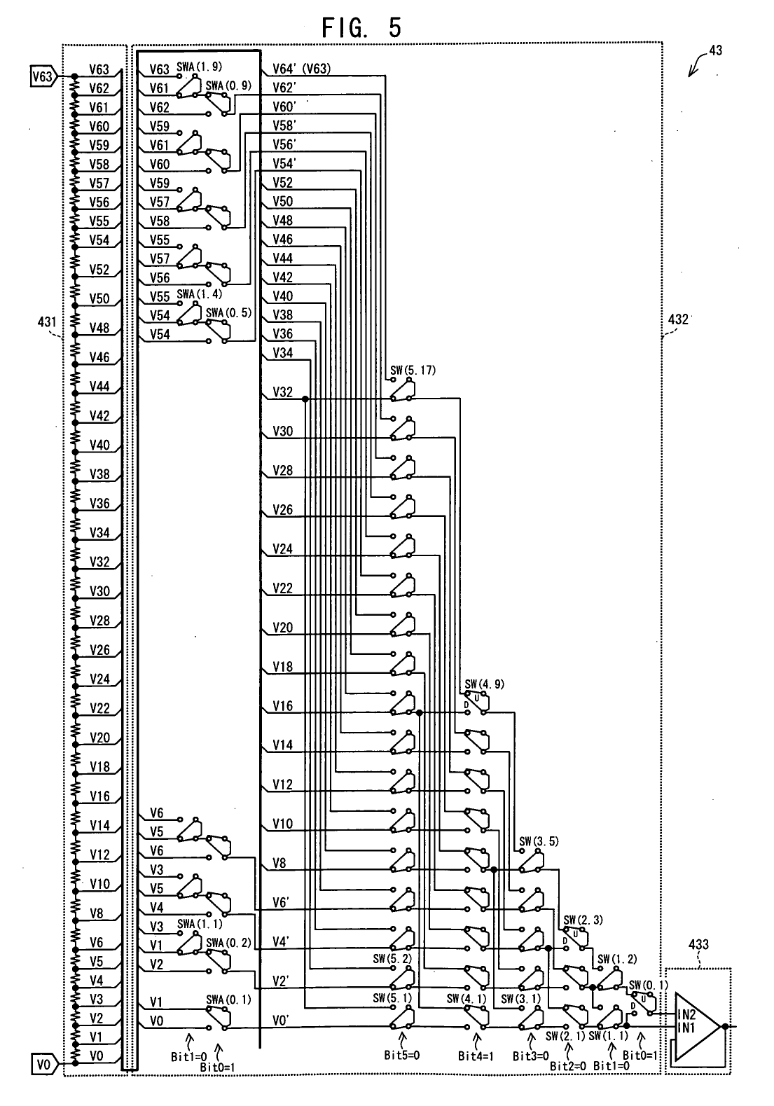

With reference to FIG. 5, the following describes how the DA converter circuit 43 operates in case where still another gray scale value is inputted from the control section 50. FIG. 5 is an explanatory drawing explaining how the DA converter circuit 43 operates in case where a gray scale value “17” which causes the bit sequence to be “001001” is inputted.

As illustrated in FIG. 5, in case where the gray scale value “17” which causes the bit sequence to be “001001” is inputted, switch pairs SW(0)U, SW(4)U, and SWA(0)U are turned on in the selector circuit 432, and adversely, switch pairs SW(0)D, SW(4)D, and SWA(0)D are turned off in the selector circuit 432. Further, switch pairs SW(5)U, SW(3)U,SW(2)U, SW(1)U, and SWA(1U are turned off, and adversely, switch pairs SW(5)D, SW(3)D, SW(2)D, SW(1)D, and SWA(1)D are turned on. Thus, the selector circuit 432 outputs a reference voltage whose voltage value is V₁₆ to the input terminal IN1 of the voltage follower circuit 433 and outputs a reference voltage whose voltage value is V₁₈ to the input terminal IN2. The voltage follower circuit 433 outputs, as a gray scale voltage Vₒᵤₜ, a voltage indicated by (V₁₆+V₁₈)/2, i.e., a voltage obtained by averaging V₁₆ inputted to the input terminal IN1 and V₁₈ inputted to the input terminal IN2.

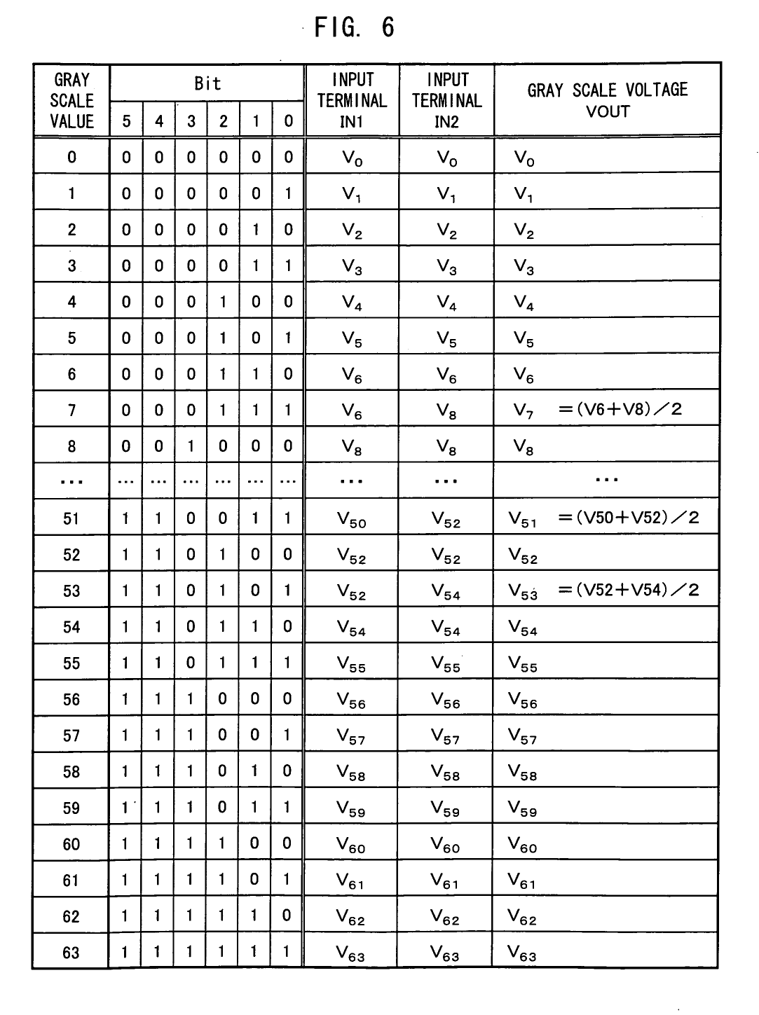

The foregoing description explained how the selector circuit 432 is configured and how the selector circuit 432 operates. These operations are summarized in FIG. 6. This represents a relationship among gray scale values each indicative of a 6-bit digital signal, outputs (reference voltages inputted to the input terminals IN1 and IN2 respectively) of the selector circuit 432, and gray scale voltages Vₒᵤₜ outputted from the voltage follower circuit 433.

As illustrated in FIG. 6, in case where the inputted gray scale value ranges “0” to “6” and ranges “54” to “63” and in case where the inputted gray scale value is an even number (Bit0 is “0”), the selector circuit 432 selects one reference voltage out of 40 reference voltages different from one another and outputs the selected reference voltage to each of the input terminals IN1 and IN2 of the voltage follower circuit 433.

Further, in case where the inputted gray scale value ranges “7” to “53” and is an odd number (Bit0 is “1”), the selector circuit 432 selects two reference voltages out of 40 reference voltages and outputs the selected reference voltages respectively to the input terminals IN1 and IN2 of the voltage follower circuit 433. Note that, the voltage follower circuit 433 of the present embodiment is configured in the same manner as in the voltage follower circuit disclosed in Patent Literature 1, so that detail descriptions thereof will be omitted here.

(Transmittance Property of Liquid Crystal Display Panel)

The following describes a relationship between an applied gray scale voltage and an optical transmittance in the liquid crystal display panel 20 (see FIG. 2). The optical transmittance of the liquid crystal display panel 20 does not necessarily change linearly relative to a change of a voltage value of a gray scale voltage applied to the liquid crystal display panel. Thus, gamma correction taking “gray scale voltage-transmittance property” of the liquid crystal display panel into consideration has to be carried out with respect to a gray scale voltage. In detail, in a lower voltage range and a higher voltage range (hereinafter, each of these ranges is referred to as “first voltage range”) out of a voltage range within which the gray scale voltage can change (V₀to V₆₃ of the present embodiment), the optical transmittance changes nonlinearly and gently relative to the change of the gray scale voltage. On the other hand, in a central range between the lower voltage range and the higher voltage range (hereinafter, referred to as “second voltage range) out of the foregoing voltage range, the optical transmittance changes linearly and steeply relative to the change of the gray scale voltage.

Thus, in order that a luminance of the liquid crystal display panel may be in proportion to the gray scale value, the DA converter circuit for converting the gray scale value into the gray scale voltage more greatly changes the gray scale voltage in the first voltage range regarding the change of the gray scale value so as to cancel the gray scale voltage-optical transmittance property of the liquid crystal display panel, and less changes the gray scale voltage in the second voltage range than the change of the gray scale value.

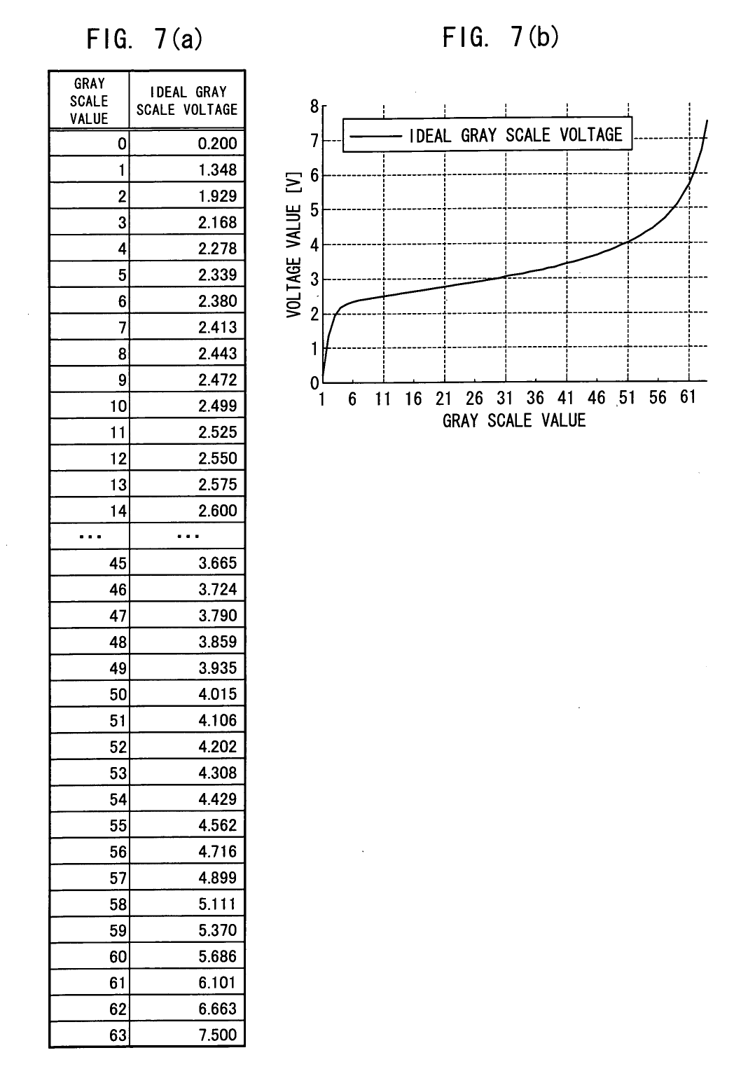

FIGS. 7(a) and 7(b) are explanatory drawings each of which illustrates an example of a relationship between 6-bit gray scale values and ideal gray scale voltages subjected to the gamma correction (hereinafter, referred to as “ideal gray scale voltage”). As illustrated in FIGS. 7(a) and 7(b), when the gray scale value ranges “0” to “5” and ranges “54” to “63”, in other words, in the first voltage range, the ideal gray scale voltage changes nonlinearly and steeply. On the other hand, when the gray scale value ranges “6” to “53”, in other words, in the second voltage range, the ideal gray scale voltage changes linearly (substantially linearly) and gently.

(Comparison with Conventional DA Converter 200)

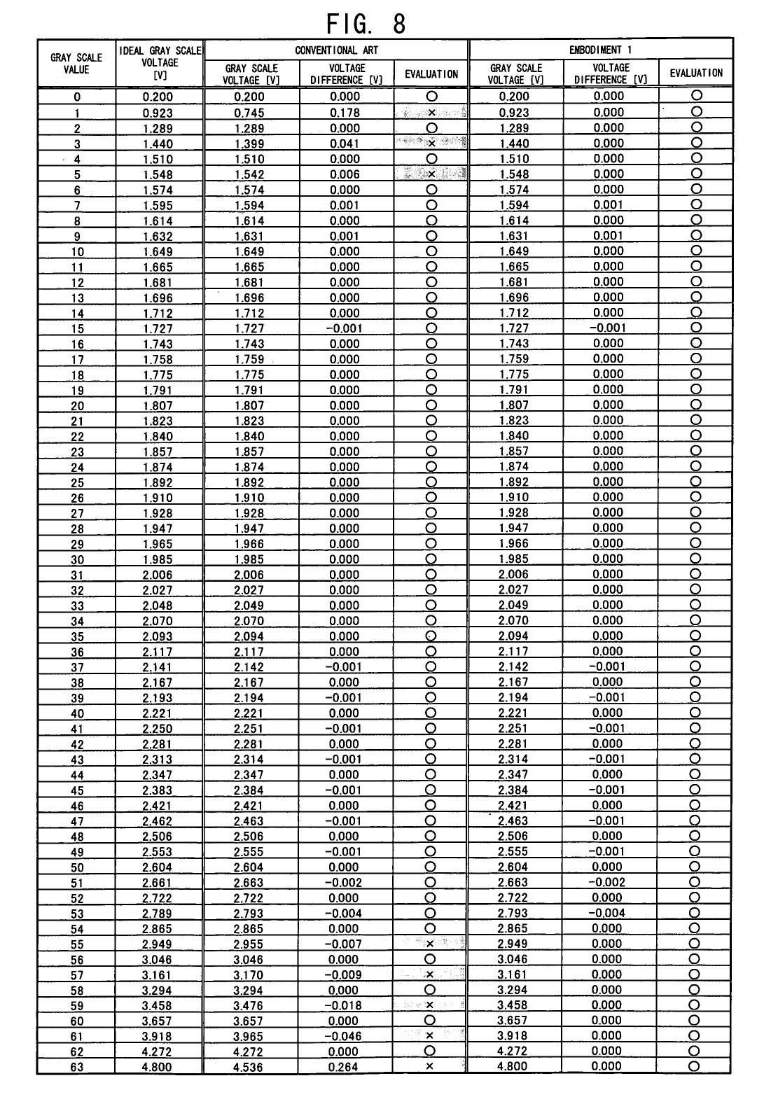

The following compares a gray scale voltage outputted by the DA converter circuit 43 of the present embodiment with a gray scale voltage outputted by the conventional DA converter 200, disclosed by Patent Literature 1, in case where a 6-bit gray scale value is inputted. FIG. 8 is an explanatory drawing which compares (i) ideal gray scale voltages respectively corresponding to the 6-bit gray scale values, (ii) gray scale voltages outputted by the conventional DA converter 200, and (iii) gray scale voltages outputted by the DA converter circuit 43 of the present embodiment.

As illustrated in FIG. 8, in case where a gray scale value is an even number, the conventional DA converter 200 outputs a reference voltage, generated by the DA converter 200, as a gray scale voltage without any modification, so that a voltage difference from the ideal gray scale voltage is 0[V]. While, in case where the gray scale value is an odd number, the DA converter 200 outputs, as a gray scale voltage, a mean value of two reference voltages respectively corresponding to two gray scale values “n−1” and “n+1” each adjacent to an inputted gray scale value “n”. For example, in case where the inputted gray scale value is “1”, a value obtained by averaging a reference voltage V₀ corresponding to a gray scale value “0” and a reference voltage V₂ corresponding to a gray scale value “2” is outputted as a gray scale voltage. Note that, the reference voltage generated by the DA converter 200 is beforehand adjusted in accordance with the ideal gray scale voltage. In other words, 32 reference voltages generated by the DA converter 200 are beforehand adjusted so as to be identical to ideal gray scale voltages of corresponding gray scale values.

Here, in the second voltage range in which the ideal gray scale voltage changes linearly relative to the change of the gray scale value, the DA converter 200 outputs a gray scale voltage, whose voltage difference from the ideal gray scale voltage is little, also in case where the gray scale value is an odd number. However, in the first voltage range in which the ideal gray scale voltage changes nonlinearly relative to the change of the gray scale value, there is a great voltage difference, in other words, there is deviation between the gray scale voltage outputted by the DA converter 200 and the ideal gray scale voltage in case where the gray scale value is an odd number. According to the example illustrated in FIG. 8, in gray scale values “1”, “3”, “5”, “55”, “57”, “59”, “61”, and “63”, a voltage difference equal to or larger than 5 [mV] occurs between the ideal gray scale voltage and the gray scale voltage outputted by the DA converter 200. Note that, in FIG. 8, a case where an absolute value of the voltage difference between the gray scale voltage outputted by the DA converter 200 and the ideal gray scale voltage is equal to or larger than 5 [mV] is represented by “×(poor)” as a result of evaluation, and a case where the absolute value is less than 5 [mV] is represented by “◯(good)” as a result of evaluation.

On the other hand, in case where the gray scale value is an even number, the DA converter circuit 43 of the present embodiment outputs the reference voltage, generated by the DA converter circuit 43, as the gray scale voltage without any modification in the same manner as in the conventional DA converter 200, so that the voltage difference from the ideal gray scale voltage is 0[V]. Further, also in case where a voltage range of an outputted gray scale voltage is within the first voltage range and an inputted gray scale value is an odd number, that is, also in case where a gray scale value “1”, “3”, “5”, “55”, “57”, “59”, “61”, or “63” is inputted, the DA converter circuit 43 causes a reference voltage generator circuit 431 (see FIG. 1) to generate reference voltages respectively corresponding to gray scale values “1”, “3”, “5”, “55”, “57”, “59”, “61”, and “63” and outputs a reference voltage, corresponding to an inputted gray scale value, without any modification. Thus, as illustrated in FIG. 8, also in case where there is inputted a gray scale value evaluated as “×” in the conventional art, the DA converter circuit 43 can output a gray scale voltage having no voltage difference from the ideal gray scale voltage.

Note that, in the present embodiment, a gray scale value indicative of a 6-bit digital signal is inputted and 64 a gray scale voltage of sixty-four gray scales is outputted correspondingly, but the present invention is not limited to this configuration, and it is needless to say that also a DA converter circuit which receives a gray scale value indicative of a bit number larger than 6 or a gray scale value indicative of a bit number smaller than 6 is included in the scope of the present invention.

Note that, in case where the bit number of the inputted gray scale value is changed, the number of reference voltages generated by the reference voltage generator circuit 431 is changed in accordance with the bit number and an arrangement of the switch pairs of the selector circuit 432 is changed accordingly.

(Method for Designing DA Converter Circuit 43)

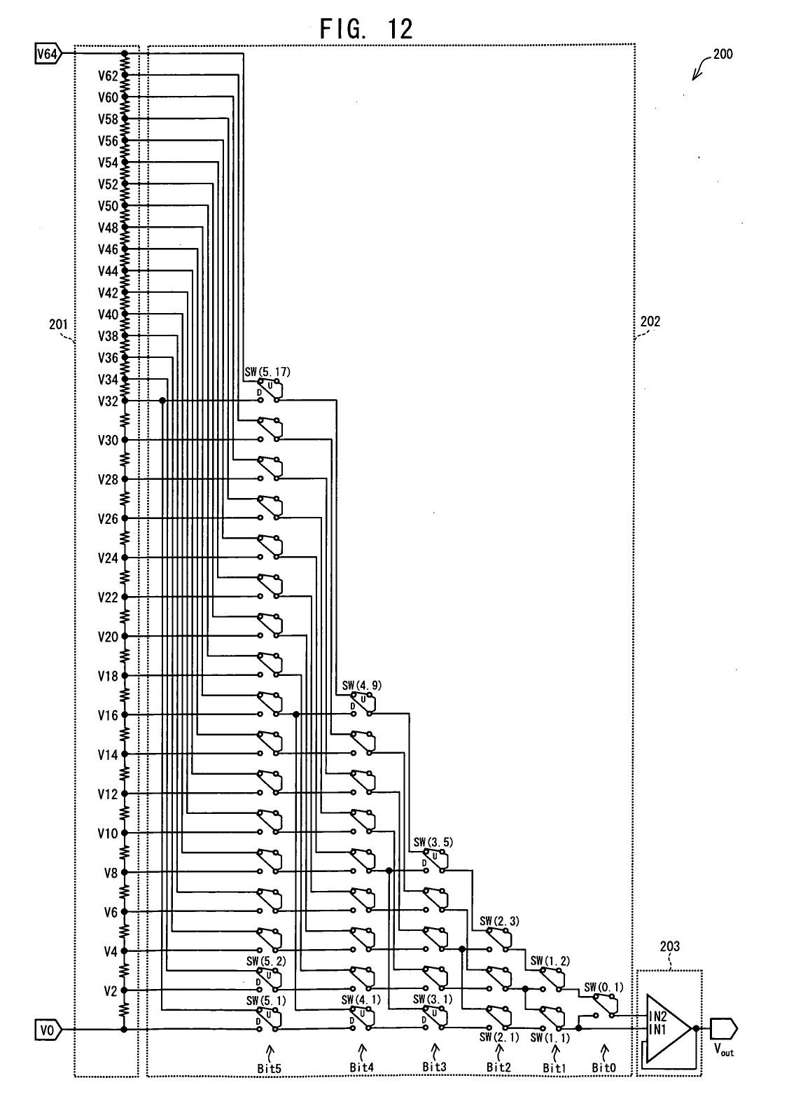

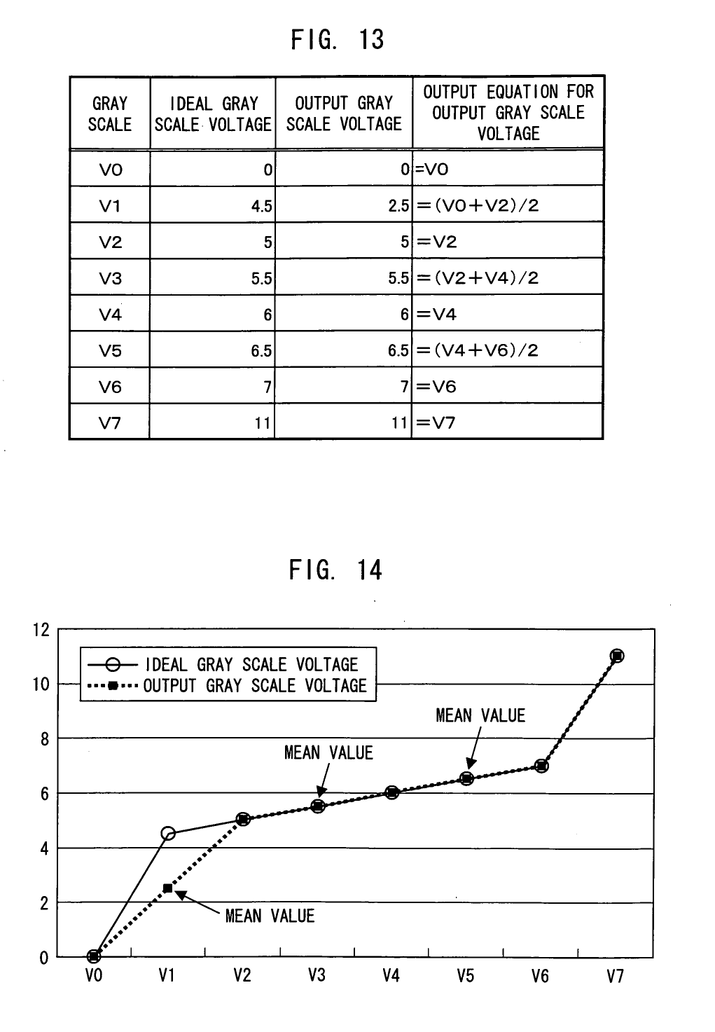

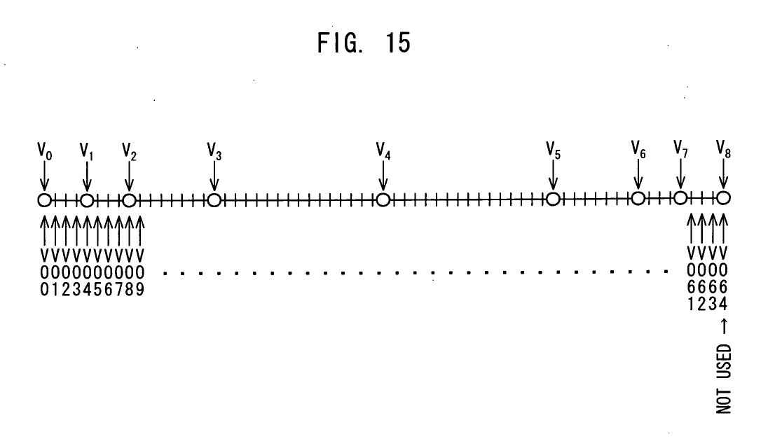

The following describes a method for designing the DA converter circuit 43 of the present embodiment, taking as an example a case of designing the DA converter circuit 43 on the basis of the conventional DA converter 200 of FIG. 12.

In case where the DA converter 200 causes a reference voltage generator circuit 201 to generate reference voltages (V₀, V₂, . . . , V₆₂, V₆₄) respectively corresponding to even-numbered gray scale values, i.e., to every two gray scales (“0”, “2”, . . . , “62”, “64”) and odd-numbered gray scale values (“1”, “3”, . . . , “63”) are inputted, a selector circuit 202 selects two reference voltages, adjacent to each other, which respectively indicates (i) a value before the inputted gray scale value and (ii) a value behind the inputted gray scale value, as reference voltages corresponding to the inputted gray scale value, and a voltage follower circuit 203 averages the selected two reference voltages, and this mean value is outputted as a gray scale voltage.

In designing the DA converter circuit 43 of the present embodiment, first, gray scale voltages outputted by the DA converter 200 in response to gray scale values are calculated in a first step (first calculation step).

Next, as illustrated in FIG. 8, each gray scale voltage respectively corresponding to each gray scale value calculated in the first calculation step is compared with an ideal gray scale voltage of that gray scale value, and a voltage difference is calculated for each gray scale value (second calculation step).

Next, it is determined whether the voltage difference calculated in the second calculation step for each gray scale value is within a predetermined range or not. A voltage range of an ideal gray scale voltage within which range the voltage differences between the gray scale values and their ideal gray scale values are within the predetermined range is regarded as the second voltage range, and a voltage range of an ideal gray scale voltage within which range the voltage differences between the gray scale values and their ideal gray scale values are out of the predetermined range is regarded as the first voltage range.

According to the example illustrated in FIG. 8, it is determined whether the voltage difference for each odd-numbered gray scale value is within a range of ±5 mV or not, and voltage values V₀ to V₅ and V₅₄ to V₆₃ whose voltage differences have been determined as being out of the range of ±5 mV are regarded as being in the first voltage range, and voltage values V₆ to V₅₃ are regarded as being in the second voltage range (voltage range determination step). Note that, in the example illustrated in FIG. 8, the predetermined range is ±5 mV, but in the designing method according to the present invention, the predetermined range can be suitably changed in accordance with a property of a liquid crystal display panel connected to the DA converter circuit to be designed.

Next, circuit configurations of the reference voltage generator circuit 201 and the selector circuit 202 are changed so that, in accordance with the first voltage range and the second voltage range which have been determined in the voltage range determination step, a reference voltage corresponding to an ideal gray scale voltage within the first voltage range is generated, and the thus generated reference voltage is outputted as a gray scale voltage, thereby manufacturing a reference voltage generator circuit 431, illustrated in FIG. 1, which is included in the DA converter circuit 43.

Further, a switch pair SWA (see FIG. 1) which can select each of reference voltages within the first voltage range is newly provided on the conventional selector circuit 202, thereby manufacturing the DA converter circuit illustrated in FIG. 1.

The technique for designing the DA converter circuit 43 on the basis of the conventional DA converter 200 is described above. This technique is applicable also to the circuit in which the first voltage range and the second voltage range are beforehand set and then the present invention is carried out as in Embodiment 1. The design is changed in this manner in case where an ideal gray scale voltage value changes due to a change or the like of a property of the panel.

First, in the first calculation step, a circuit whose design is to be changed is used to calculate a gray scale voltage to be outputted.

Next, in the second calculation step, the changed ideal gray scale voltage value is used to calculate a voltage difference for each gray scale value.

Next, in the voltage range determination step, the first voltage range and the second voltage range are changed.

Next, circuit configurations of the reference voltage generator circuit and the selector circuit are changed so that, in accordance with the first voltage range and the second voltage range which have been determined in the voltage range determination step, a reference voltage corresponding to an ideal gray scale voltage within the first voltage range is generated, and the thus generated reference voltage is outputted as a gray scale voltage.

### Embodiment 2

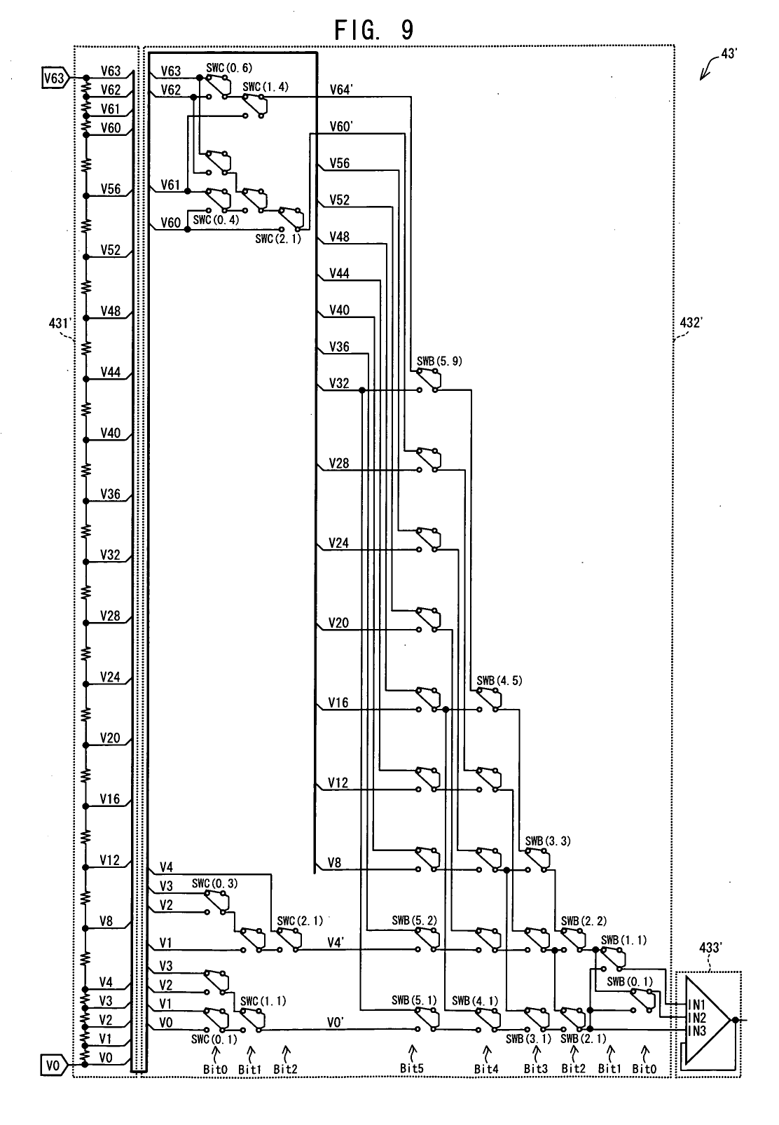

Next, Embodiment 2 of the present invention is described below with reference to FIG. 9. In a description of Embodiment 2, only a part different from Embodiment 1 is described, whereas a description of a part overlapping Embodiment 1 is omitted.

First, Embodiment 2 of the present invention is different from Embodiment 1 of the present invention in terms that a source driver circuit 40 (see FIG. 3) includes a DA converter circuit 43′ instead of a DA converter circuit 43. FIG. 9 is a block diagram of the DA converter circuit 43′, which is capable of outputting sixty-four levels of gray scale voltages in accordance with a six-bit gray scale value.

(Configuration of DA Converter Circuit 43′)

As shown in FIG. 9, the DA converter circuit 43′ includes a reference voltage generator circuit 431′, (generating section), a selector circuit 432′ (selecting section), and a voltage follower circuit 433′ (output section).

(Configuration and Operation of Reference Voltage Generator Circuit 431′)

The reference voltage generator circuit 431′ is a resistance voltage divider circuit in which (i) a plurality of resistor elements is connected with one another in series, and (ii) reference voltages are generated at respective connection parts, each of the connection parts being provided between adjacent ones of the resistor elements. In the reference voltage generator circuit 431′, twenty-one resistor elements are connected with one another in series. The reference voltage generator circuit 431′ has one terminal that is applied with a maximum value (V₆₃) of a gray scale voltage, and the other terminal that is applied with a minimum value (V₀) of a gray scale voltage. Thus, in the reference voltage generator circuit 431′, twenty-two levels of reference voltages are generated, at respective terminals of the resistor elements, in proportion to respective resistance values of the resistor elements.

The reference voltage generator circuit 431′ generates, for voltage ranges of gray scale voltages corresponding to gray scale values of “0” through “4”, and “61” through “63”, respectively (voltage ranges of gray scale voltage V₀ through V₄ and V₆₁ though V₆₃: hereinafter, referred to as third voltage ranges), eight levels of reference voltages so that the number of the reference voltage to be generated and the number of the gray scale voltages in the above voltage ranges are the same. Further, the reference voltage generator circuit 431′ generates, for a voltage range of gray scale voltages corresponding to gray scale values of “5” through “60” (a voltage range of gray scale voltages V₅ though V₅₀: hereinafter, referred to as a fourth voltage range), fourteen levels of reference voltages so that the number of the reference voltages to be generated is one fourth of the number of the gray scale voltages in the above voltage range. That is, the reference voltage generator circuit 431′ generates, for the third voltage range, the reference voltages each corresponding to one gray scale voltage, and for the fourth voltage range, on the other hand, the reference voltages each corresponding to a gray scale voltage of every four gray scales. The reference voltage generator circuit 431′ then outputs the thus generated twenty-two levels of reference voltages to the selector circuit 432′.

(Configuration and Operation of Selector Circuit 432′)

The selector circuit 432′ selects one or two reference voltages from the twenty-two levels of the reference voltages in accordance with a six-bit gray scale value, and thereby outputs a reference voltage corresponding to the six-bit gray scale value. The selector circuit 432′ can be formed by members such as an analogue switch or the like. Examples of such an analogue switch includes a MOS transistor, a transmission gate, and the like. Each of such switches is constituted by a pair of two switches, and performs output by selecting one of two inputs signals.

In FIG. 9, some of switch pairs are shown by SWB (X, Y), and the others of switch pairs are shown by SWC (X, Y), where X corresponds to a bit number (Bit 1, Bit 2, . . . , Bit 5) of a gray scale value, and Y shows a longitudinal position of a switch pair in the drawing, Y being increased to 1, 2, and so on upwardly from the bottom of the drawing. Further, of two switches constituting a switch pair, the upper one in the drawing is given a reference U and the lower one in the drawing is given a reference D, so as to distinguish the switches. For example, a switch pair, which operates in accordance with Bit 5 (MSB) of a six-bit gray scale value and which is a third switch pair from the bottom of the drawing, is shown by SWB (5, 3). Also, of the two switches constituting the switch pair, the upper one is shown by SWB (5, 3)U and the lower one is shown by SWB (5, 3)D.

No number corresponding to Y is given so as to show a switch pair in a case where switch pairs lining up in the longitudinal direction of the drawing are referred collectively, i.e., in a case where switch pairs operating in accordance with a same bit number are referred collectively. For example, switch pairs operating in accordance with Bit 5 of a gray scale value, such as switch pairs SWB (5, 1), SWB (5, 2), and so forth, are collectively shown by SWB (5). Further, no number corresponding to Y is given so as to show a switch, in a case where upper switches of respective switch pairs which operate in accordance with a certain bit number of a gray scale values are referred collectively. For example, upper switches of respective switch pairs operating in accordance with Bit 4 of a gray scale value, such as switches SWB (4, 1)U, SWB (4, 2)U, and so fourth, are shown by SWB (4)U. This is also true for lower switches of the respective switch pairs. Switch pairs SWC (X, Y) are collectively shown in a same way as switch pairs SWB (X, Y) are collectively shown in the above description. Further, in a case where switch pairs SWB (0), SWB (1), . . . SWB (5) included by the selector circuit 432′ are referred collectively, the switch pairs SWB (0) through SWB (5) are shown by SWB, and in a case where switch pairs SWC (0) and SWC (1) included by the selector circuit 432′ are referred collectively, the switch pairs SWC (0) and SWC (1) are shown by SWC.

(Configurational Relation of Switches)

Next, a configurational relation of switches operating in accordance with each bit of a gray scale value is described. Switches pairs operating in accordance with Bit 5 (MSB) of a six-bit gray scale include nine pairs, which are switch pairs SWB (5, 1) through SWB (5, 9), each being constituted by two switches U and D.

A switch SWB (5, 1) D has one end via which a reference voltage V₀′ is inputted from a common terminal of a switch pair SWC (1, 1), and a switch SWB (5, 1) U has one end via which a reference voltage V₃₂ is inputted. Further, the switches SWB (5, 1) U and the SWB (5, 1) D have the other ends, respectively, which are connected with each other so as to constitute a common terminal. A switch SWB (5, 2) D has one end via which a reference voltage V₄′ is inputted from a common terminal of a SWC (2, 1), and a switch SWB (5, 2) U has one end via which a reference voltage V₃₆ is inputted. Further, the switches SWB (5, 2) U and the SWB (5, 2) D have the other ends, respectively, which are connected with each other so as to constitute a common terminal. In the drawing, the reference voltage V₀′ is any one of reference voltages V₀ through V₃ that is selected by switch pairs SWC (0, 1), SWC (0, 2), and SWC (1, 1), and the reference voltage V₄′ is any one of reference voltages V₁ through V₄ that is selected by switch pairs SWC (0, 3), SWC (1, 2), and SWC (2, 1).

Furthermore, a switch pair SWB (5, 3)D has one end via which a reference voltage V₈ is inputted, and the switch pair SWB (5, 3)U has one end via which a reference voltage V₄₀ is inputted. Further, the switches SWB (5, 3)U and SWB (5, 3)D have the other ends, respectively, which are connected with each other so as to constitute a common terminal. Each of switch pairs SWB (5, 4) through SWB (5, 7) are configured in a same way, so that (i) a switch SWB (5, f)U has one end via which a reference voltage V_{4(f-1)} is inputted, and (ii) a switch SWB (5, f)U has one end via which a reference voltage V_{4(f-1)+32} is inputted, where f=3, 4, . . . , 7. Also, the switches SWB (5, f)D and SWB (5, f)U have the other ends, respectively, which are connected with each other so as to constitute a common terminal.

Furthermore, a switch SWB (5, 8)D has one end via which a reference voltage V₂₈ is inputted, and a switch SWB (5, 8)U has one end via which a reference voltage V₆₀′ is inputted from a common terminal of a switch pair SWC (2, 2). Further, the switches SWB (5, 8)U and SWB (5, 8)D have the other ends, respectively, which are connected with each other so as to constitute a common terminal. A switch SWB (5, 9)D has one end via which a reference voltage V₃₂ is inputted, and a switch SWB (5, 9)U has one end via which a reference voltage V₆₄′ is inputted from a common terminal of a switch pair SWC (1, 4). Further, the switches SWB (5, 9)U and SWB (5, 9)D have the other ends, respectively, which are connected with each other so as to constitute a common terminal. In the drawing, the reference voltage V₆₀′ is any one of reference voltages V₆₀ through V₆₃ that is selected by switch pairs SWC (0, 4), SWC (0, 5), SWC (1, 3), and SWC (2, 2), and the reference voltage V₆₄′ is any one of the reference voltages V₆₁ through V₆₃ that is selected by switch pairs SWC (0, 6) and SWC (1, 4).

The switch pairs SWB (5) are in conduction with one another, such that in a case where a gray scale value whose Bit 5 value is “0” is inputted, lower switches SWB (5)D are connected (being turned ON), and, in contrast, upper switches SWB (5)U are disconnected. On the other hand, in a case where a gray scale value whose Bit 5 value is “1” is inputted, the lower switches SWB (5)D are disconnected (being turned OFF), and, in contrast, the upper switches SWB (5)U are connected (being turned ON).

Next, switch pairs operating in accordance with Bit 4 of a gray scale value include five switch pairs, which are switch pairs SWB (4, 1) through SWB (4, 5), each being constituted by two switches U and D, as in the case of switch pairs (5).

A switch SWB (4, 1)D has one end connected with the common terminal of the switch pair SWB (5, 1), and a switch SWB (4, 1)U has one end connected with a common terminal of the switch pair SWB (5, 5). Further, the switches SWB (4, 1)D and SWB (4, 1)U have the other ends, respectively, which are connected with each other so as to constitute a common terminal. Similarly, a switch SWB (4, e)D has one end connected with a common terminal of a switch pair SWB (5, e), and a switch SWB (4, e)U has one end connected with a common terminal of a switch pair SWB (5, e+4), where e=1, 2, . . . , 5. Further, the switches SWB (4, e)D and SWB (4, e)U have the other ends, respectively, which are connected with each other so as to constitute a common terminal.

Such switch pairs SWB (4) are in conjunction with one another, so that in a case where a gray scale value whose Bit 4 value is “0” is inputted, switches SWB (4)D, lower switches, are connected (being turned ON), and in contrast, switches SWB (4)U, upper switches, are disconnected (being tuned OFF). On the other hand, in a case where a gray scale value whose Bit 4 value is “1” is inputted, the switches SWB (4)D, the lower switches, are disconnected (being turned OFF), and in contrast, the switches SWB (4)U, the upper switches, are connected (being turned ON).

Next, switch pairs operating in accordance with Bit 3 of a gray scale value include three switch pairs, which are switch pairs SWB (3, 1) through SWB (3, 3), each being constituted by two switches U and D, as in earlier cases.

A switch SWB (3, 1)D has one end connected with the common terminal of the switch pair SWB (4, 1), and a switch SWB (3, 1)U has one end connected with a common terminal of a switch pair SWB (4, 3). Further, the switches SWB (3, 1)D and SWB (3, 1)U have the other ends, respectively, which are connected with each other so as to constitute a common terminal. Similarly, a switch SWB (3, d)D has one end connected with a common terminal of a switch pair SWB (4, d), and a switch SWB (3, d)U has one end connected with a common terminal of a switch pair SWB (4, d+2), where e=1, 2, 3. Further, the switches SWB (3, d)D and SWB (3, d)U have the other ends, respectively, which are connected with each other so as to constitute a common terminal.

Such switch pairs SWB (3) are in conjunction with one another, so that in a case where a gray scale value whose Bit 3 value is “0” is inputted, switches SWB (3)D, lower switches, are connected (being turned ON), and in contrast, switches SWB (3)U, upper switches, are disconnected (being turned OFF). On the other hand, in a case where a gray scale value whose Bit 3 value is “1” is inputted, the switches SWB (3)D, the lower switches, are disconnected (being turned OFF), and in contrast, the switches SWB (3)U, the upper switches, are connected (being turned ON).

Next, switch pairs operating in accordance with Bit 2 of a gray scale value include two switch pairs SWB (2, 1) and SWB (2, 2) and two switch pairs SWC (2, 1) and SWC (2, 2), each being constituted by two switches U and D, as in the earlier cases.

A switch SWB (2, 1)D has one end connected with the common terminal of the switch pair SWB (3, 1), and a switch SWB (2, 1)U has one end connected with the common terminal of the switch pair SWB (3, 2). Further, the switches SWB (2, 1)D and SWB (2, 1)U have the other ends, respectively, which are connected with each other so as to constitute a common terminal. Also, a switch SWB (2, 2)D has one end connected with a common terminal of a switch pair SWB (3, 2), and the switch SWB (2, 2)U has one end connected with a common terminal of a switch pair SWB (3, 3). Further, the switches SWB (2, 2)D and SWB (2, 2)U have the other ends, respectively, which are connected with each other so as to constitute a common terminal.

Such switch pairs SWB (2) are in conjunction with one another, so that in a case where a gray scale value whose Bit 2 value is “0” is inputted, switches SWB (2)D, lower switches, are connected (being turned ON), and in contrast, switches SWB (2)U, upper switches, are disconnected (being turned OFF). On the other hand, in a case where a gray scale value whose Bit 2 value is “1” is inputted, the switches SWB (2)D, the lower switches, are disconnected (being turned OFF), and in contrast, the switches SWB (2)U, the upper switches, are connected (being turned ON).

Furthermore, a switch SWC (2, 1)D has one end connected with a common terminal of a switch pair SWC (1, 2), and a switch SWC (2, 1)U has one end via which the reference voltage V₄ is inputted. Further, the switches SWC (2, 1)D and SWC (2, 1)U have the other ends, respectively, which are connected with each other so as to constitute a common terminal. A switch SWC (2, 2)D has one end via which the reference voltage V₆₀ is inputted, and a switch SWC (2, 2)U has one end connected with a common terminal of a switch pair SWC (1, 3). Further, the switches SWC (2, 2)D and SWC (2, 2)U have the other ends, respectively, which are connected with each other so as to constitute a common terminal.

Such switch pairs SWC (2) are in conjunction with one another, so that in a case where a gray scale value whose Bit 2 value is “0” is inputted, switches SWC (2)D, lower switches, are connected (being turned ON), and in contrast, switches SWC (2)U, upper switches, are disconnected (being turned OFF). On the other hand, in a case where a gray scale value whose Bit 2 value is “1” is inputted, the switches SWC (2)D, the lower switches, are disconnected (being turned OFF), and in contrast, the switches SWC (2)U, the upper switches, are connected (being turned ON).

Next, switch pairs operating in accordance with Bit 1 of a gray scale value include one switch pair SWB (1, 1) and four switch pairs SWC (1, 1) through SWC (1, 4), each being constituted by two switches U and D, as in the earlier cases.

A switch SWB (1, 1)D has one end connected with the common terminal of the switch SWB (2, 1), and a switch SWB (1, 1)U has one end connected with a common terminal of a switch pair SWB (2, 2). Further, the switches SWB (1, 1)U and SWB (1, 1)U have the other ends, respectively, which are connected with each other so as to constitute a common terminal, the common terminal being connected with an input terminal IN1 of the voltage follower circuit 433′.

In the switch SWB (1, 1), in a case where a gray scale value whose Bit 1 value is “0” is inputted, the switch SWB (1, 1)D, a lower switch, is connected (being turned ON), and in contrast, the switch SWB (1, 1)D, an upper switch, is disconnected (being turned OFF). On the other hand, in a case where a gray scale value whose Bit 1 value is “1” is inputted, the switch SWB (1, 1)D, the lower switch, is disconnected (being turned OFF), and in contrast, the switch SWB (1, 1)U, the upper switch, is connected (being turned ON).

Furthermore, a switch SWC (1, 1)D has one end connected with a common terminal of a switch pair SWC (0, 1), and a switch SWC (1, 1)U has one end connected with a common terminal of a switch pair SWC (0, 2). A switch SWC (1, 2)D has one end via which the reference voltage V₁ is inputted, and a switch SWC (0, 3)U has one end connected with a common terminal of a switch pair SWC (0, 3). A switch SWC (1, 3)D has one end connected with a common terminal of a switch pair SWC (0, 4), and a switch SWC (1, 3)U has one end connected with a common terminal of a switch pair SWC (0, 5). A switch SWC (1, 4)D has one end via which the reference voltage V₆₁ is inputted, and a switch SWC (1, 4)U has one end connected with a common terminal of a switch pair SWC (0, 6). Further, switches SWB (1)U have the other ends, respectively, each of which are connected with corresponding one of the other ends of switches SWB (1)D so as to constitute a common terminal.

Such switch pairs SWC (1) are in conjunction with one another, so that in a case where a gray scale value whose Bit 1 value is “0” is inputted, switches SWC (1)D, lower switches, are connected (being turned ON), and in contrast, switches SWC (1)U, upper switches, are disconnected (being turned OFF). On the other hand, in a case where a gray scale value whose Bit 1 value is “1” is inputted, the switches SWC (1)D, the lower switches, are disconnected (being turned OFF), and in contrast, the switches SWC (1)U, the upper switches, are connected (being turned ON).

Next, switch pairs operating in accordance with Bit 0 of a gray scale value include one switch pair SWB (0, 1) and six switch pairs SWC (0, 1) through SWC (0, 6), each being constituted by two switches U and D, as in the earlier cases.

A switch SWB (0, 1)D has one end connected with the common terminal of the switch SWB (2, 1), and a switch SWB (0, 1)U has one end connected with the common terminal of the switch pair SWB (2, 2). Further, the switches SWB (0, 1)D and SWB (0, 1)U have the other ends, respectively, which are connected with each other so as to constitute a common terminal, the common terminal being connected with an input terminal IN2 of the voltage follower circuit 433′. The switch pair SWB (2, 1) has the common terminal that is connected with one end of the switch SWB (0, 1)D and one end of the switch SWB (1, 1)D, as described above, and also connected with an input terminal IN3 of the voltage follower circuit 433′.

Furthermore, a switch SWC (0, 1)D has one end connected via which the reference voltage V₀ is inputted, and a switch SWC (0, 1)U has one end via which the reference voltage V₁ is inputted. A switch SWC (0, 2)D has one end via which the reference voltage V₂ is inputted, and a switch SWC (0, 2)U has one end via which the reference voltage V₃ is inputted. A switch SWC (0, 3)D has one end via which the reference voltage V₂ is inputted, and a switch SWC (0, 3)U has one end via which the reference voltage V₃ is inputted. A switch SWC (0, 4)D has one end via which the reference voltage V₆₀ is inputted, and a switch SWC (0, 4)U has one end via which the reference voltage V₆₁ is inputted. A switch SWC (0, 5)D has one end via which the reference voltage V₆₂ is inputted, and a switch SWC (0, 5)U has one end via which the reference voltage V₆₃ is inputted. A switch SWC (0, 6)D has one end via which the reference voltage V₆₂ is inputted, and a switch SWC (0, 6)U has one end via which the reference voltage V₆₃ is inputted. Further, switches SWC (0)U has the other ends, respectively, each being connected with corresponding one of the other ends of switches SWC (0)D so as to constitute a common terminal.

Such switch pairs SWC (0) are in conjunction with one another, so that in a case where a gray scale value whose Bit 0 value is “0” is inputted, the switches SWC (0)D, lower switches, are connected (being turned ON), and in contrast, the switches SWC (0)U, upper switches, are disconnected (being turned OFF). On the other hand, in a case where a gray scale value whose Bit 0 value is “1” is inputted, the switches SWC (0)D, the lower switches, are disconnected (being turned OFF), and in contrast, the switches SWC (0)U, the upper switches, are connected (being turned ON).

As described, in the selector circuit 432′, the switch pairs SWB and the switch pairs SWC operate in accordance with a six-bit gray scale value inputted from the control section 50 (see FIG. 2), so that three reference voltages, each corresponding to the six-bit gray scale value, out of twenty-two levels of the reference voltages generated in the reference voltage generator circuit 431′ are outputted to the voltage follower circuit 433′.

More specifically, the selector circuit 432′ selects one reference voltage corresponding to an inputted gray scale value, and then outputs the same reference voltage to each of the input terminals (IN1 through IN3) of the voltage follower circuit 433′, in a case where (i) a gray scale value (any of gray scale values of “0” through “4” and “61” through “63”) corresponding to a gray scale voltage in the third voltage ranges is inputted or (ii) a gray scale value, whose value is a multiple of “4” (a gray scale value of “4a”, where a=2 through 15) and corresponds to a gray scale voltage in the fourth voltage range. For example, in a case where a gray scale value of “1” is inputted, the selector circuit 432′ outputs the reference voltage V₁ to each of the input terminals (IN1 through IN3) of the voltage follower circuit 433′. Further, in a case where a gray scale value of “12” is inputted, the selector circuit 432′ outputs the reference voltage V₁₂ to each of the input terminals (IN1 through IN3) of the voltage follower circuit 433′.

On the other hand, in a case where the gray scale value (any of gray scale values of “4a-3”, “4a-2”, and “4a-1”), whose value is other than a multiple of 4 and corresponds to a gray scale voltage in the fourth voltage range, is inputted, the selector circuit 432′ selects two reference voltages (V₄₍ₐ₋₁₎ and V₄ₐ) which correspond to the inputted gray scale value, and performs output to each of the input terminals (IN1 through IN3) in such a manner that the following condition is satisfied.

In a case where the gray scale value of “4a-3” is inputted, inputted voltages (V_{IN1}, V_{IN2}, V_{IN3})=(V₄₍ₐ₋₁₎, V₄ₐ, V₄₍ₐ₋₁₎). In a case where the gray scale voltage of “4a-2” is inputted, inputted voltages (V_{IN1}, V_{IN2}, V_{IN3})=(V₄ₐ, V₄₍ₐ₋₁₎, V₄₍ₐ₋₁₎). In a case where the gray scale value of “4a-1” is inputted, inputted voltages (V_{IN1}, V_{IN2}, V_{IN3})=(V₄ₐ, V₄ₐ, V₄₍ₐ₋₁₎). For example, in a case where a gray scale value of “11” is inputted, the selector circuit 432′ selects the two reference voltages V₈ and V₁₂, and then outputs the reference voltage V₁₂ to each of the inputted terminals IN1 and IN2 of the voltage follower circuit 433′, and the reference voltage V₈ to the input terminal IN3.

(Configuration and Operation of Voltage Follower Circuit 433′)

Configuration and operation of the voltage follower circuit 433′ are described next. In the voltage follower circuit 433′, three reference voltages outputted from the selector circuit 432′ are inputted via the respective input terminals IN1 through IN3. In the following description, a reference voltage inputted via the input terminal IN1 is V_{IN1}, a reference voltage inputted via the input terminal IN2 is V_{IN2}, and a reference voltage inputted via the input terminal IN3 is V_{IN3}.

As shown in FIG. 9, the voltage follower circuit 433′ outputs, based on the respective input voltages (V_{IN1}, V_{IN2}, and V_{IN3}) inputted via the three input terminals IN1, IN2, and IN3, a gray scale voltage V_{OUT} to a liquid crystal panel 20 in such a manner that “V_{OUT}=(V_{IN2}+V_{IN3}+V_{IN1}×2)/4” is satisfied.

As described above, in the voltage follower circuit 433′, an input via the input terminal IN1 is weighted by two times.

Thus, in a case where (i) the gray scale value (any of gray scale values of “0” through “4” and “61” through “63”), which corresponds to a gray scale voltage in the third range, is inputted to the selector circuit 432′, or (ii) the gray scale value (a gray scale value of “4a”, where a=2 through 15), whose value is a multiple of 4 and corresponds to a gray scale voltage in the fourth range, is inputted to the selector circuit 432′, the voltage follower circuit 433′ receives input of one reference voltage, which corresponds to the inputted gray scale value, via each of its input terminals IN1, IN2, and IN3, and as a result, directly outputs the thus inputted one reference voltage as a gray scale voltage V_{OUT}.

On the other hand, in a case where the gray scale value (any of gray scale values of “4a-3”, “4a-2”, “4a-1”), whose value is other than a multiple of 4 and corresponds to a gray scale voltage in the fourth voltage range, is inputted to the selector circuit 432′, the voltage follower circuit 433′ receives input of two reference voltages from the selector circuit 432′, and then performs output of a mean value interpolated between the two reference voltages, more specifically, the voltage follower circuit 433′ performs output of a gray scale voltage V_{OUT} in such a manner that the following condition is satisfied.

In a case where the gray scale value of “4a-3” is inputted, i.e., in a case where inputted voltages (V_{IN1}, V_{IN2}, V_{IN3})=(V₄₍ₐ₋₁₎, V₄ₐ, V₄₍ₐ₋₁₎), V_{OUT}=(V₄ₐ+V₄₍ₐ₋₁₎×3)/4. Further, in a case where the gray scale value of “4a-2” is inputted, i.e., input voltages (V_{IN1}, V_{IN2}, V_{IN3})=(V₄ₐ, V₄₍ₐ₋₁₎, V₄₍ₐ₋₁₎), V_{OUT}=(V₄ₐ×2+V₄₍ₐ₋₁₎×2)/4. Furthermore, in a case where the gray scale value of “4a-1” is inputted, i.e., in a case where input voltages (V_{IN1}, V_{IN2}, V_{IN3})=(V₄ₐ, V₄ₐ, V₄₍ₐ₋₁₎), V_{OUT}=(V₄ₐ×3+V₄₍ₐ₋₁₎)/4.

As described, the DA converter circuit 43′, including the reference voltage generator circuit 431′, the selector circuit 432′, and the voltage follower circuit 433′, is capable of outputting a gray scale voltage of sixty-four gray scales, to the liquid crystal display panel 20 (see FIG. 2), in accordance with a gray scale value of sixty-four gray scales, and in the DA converter circuit 43′, it is possible that the number of resistor elements and that of the switch pairs be reduced as compared to the DA converter circuit 43 described in Embodiment 1.

The voltage follower circuit of the present embodiment is disclosed in detail in Japanese Patent Application Publication, Tokukai, No. 2002-43944 (corresponding to U.S. Pat. No. 6,441,763).

### Embodiment 3

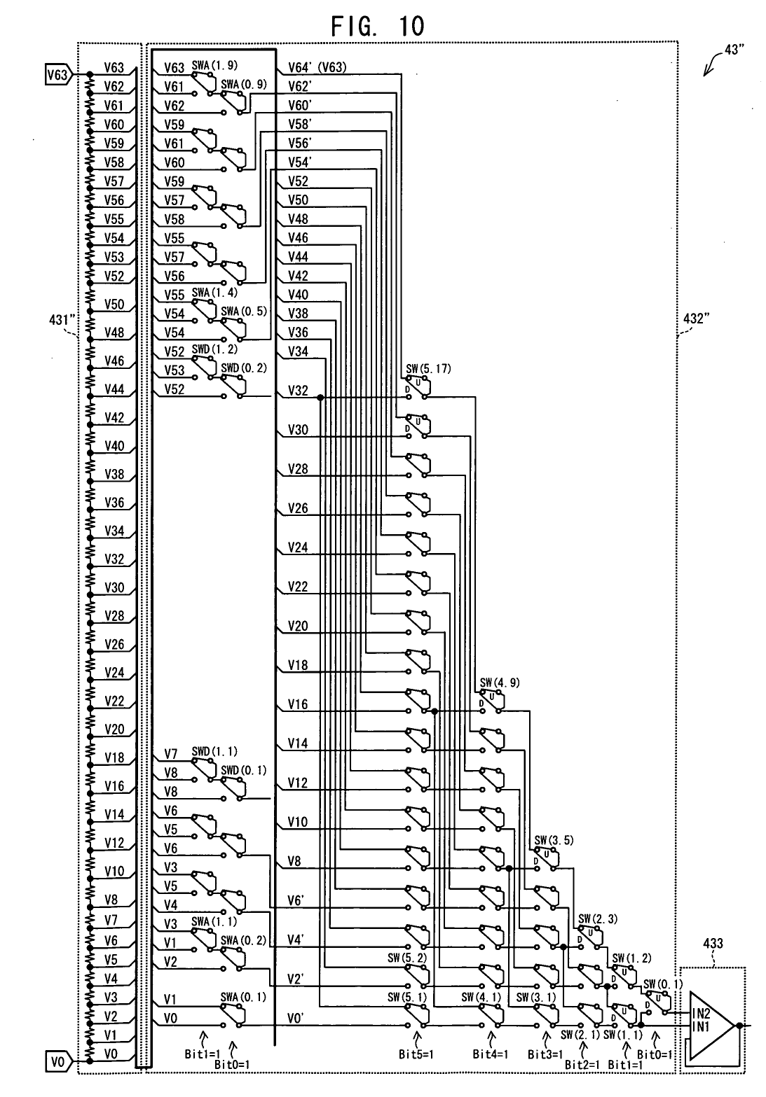

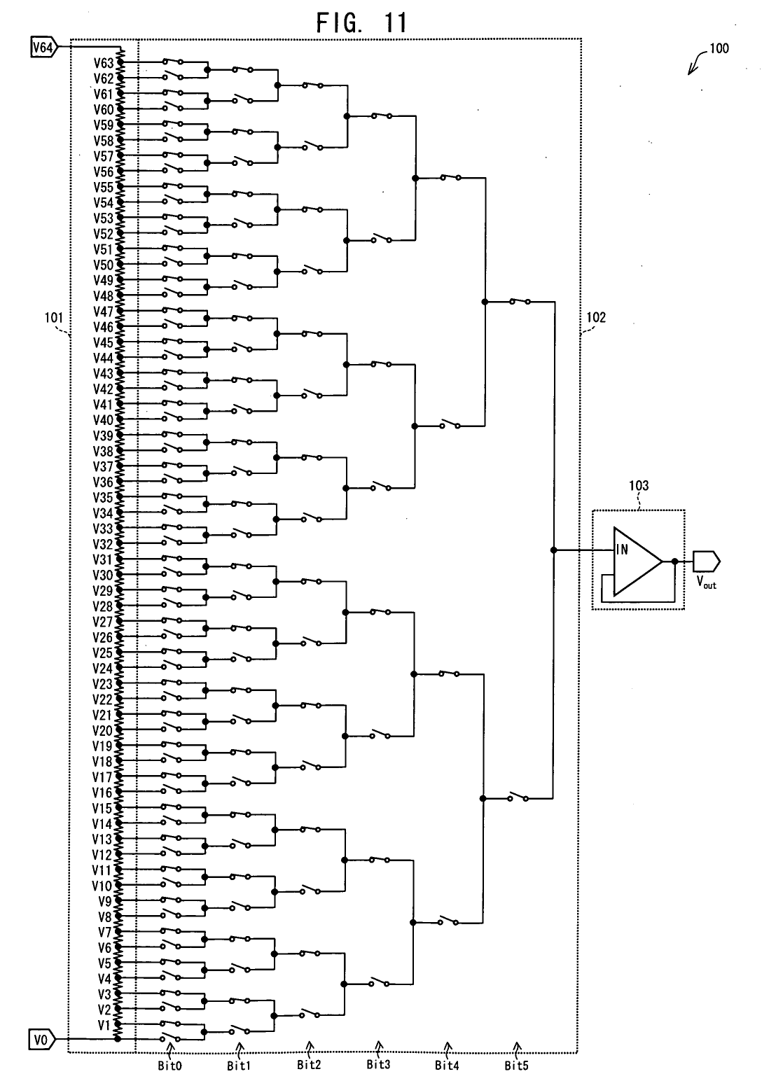

Next, with reference to FIG. 10, the following describes Embodiment 3 according to the present invention. Note that, a DA converter circuit 43″ of Embodiment 3 is a modification example of the DA converter circuit 43 of Embodiment 1, so that Embodiment 3 describes only differences from Embodiment 1 and the same explanations will not be repeated. Further, FIG. 10 is a circuit diagram illustrating a configuration of the DA converter circuit 43″ according to the present embodiment.

First, as illustrated in FIG. 10, the DA converter circuit 43″ of the present embodiment is different from the DA converter circuit 43 of Embodiment 1 in that a reference voltage generator circuit 431″ (generating section) includes two more resistor elements compared with the reference voltage generator circuit 431 and generates reference voltages V₇ and V₅₃. Further, the DA converter circuit 43″ of the present embodiment is different from the DA converter circuit 43 of Embodiment 1 also in that a selector circuit 432″ (selecting section) includes four switch pairs (preliminary switching elements), i.e., SWD (1, 1), SWD (1, 2), SWD (0, 1), and SWD (0, 2) in addition to the switch pairs of the selector circuit 432 of Embodiment 1. As in the switch pair SW of Embodiment 1, each of the switch pairs SWD (1, 1), SWD (1, 2), SWD (0, 1), and SWD (0, 2) is made up of two switches U and D. In the following description, when the switch pairs SWD (1, 1), SWD (1, 2), SWD (0, 1), and SWD (0, 2) are represented, these switch pairs are represented in the same manner as the switch pairs SW of Embodiment 1.

One end of SWD (0, 1) D is supplied with an input of V₈, and one end of SWD (0, 1) U is connected to a common terminal of SWD (1, 1). Further, the other end of the SWD (0, 1) U and the other end of SWD (0, 1) D are connected to each other and form a common terminal. Further, one end of SWD (0, 2) D is supplied with an input of V₅₂, and one end of SWD (0, 2) U is connected to a common terminal of SWD (1, 2). Further, the other end of SWD (0, 2) U and the other end of SWD (0, 2) D are connected to each other and form a common terminal.

One end of SWD (1, 1) D is supplied with an input of V₈, and one end of SWD (1, 1) U is supplied with an input of V₇. Further, the other end of SWD (1, 1) U and the other end of SWD (1, 1) D are connected to each other and form a common terminal. Further, one end of SWD (1, 2) D is supplied with an input of V₅₃, and one end of SWD (1, 2) D is supplied with an input of V₅₂. Further, the other end of SWD (1, 2) U and the other end of SWD (1, 2) D are connected to each other and form a common terminal.

Here, as illustrated in FIG. 10, the common terminals of SWD (0, 1) and SWD (0, 2) are not connected to any switch pairs. This is based on the following reason.

In case of changing the property of the liquid crystal display panel, only an ideal voltage value of a gray scale voltage to be outputted may change while a gray scale number of a gray scale value inputted to the DA converter circuit 43″ and a gray scale number of a gray scale voltage to be outputted remain the same. In this case, in the reference voltage generator circuit 431″ of the DA converter circuit 43″, a ratio at which the resistor element divides a resistance is changed.

In the DA converter circuit 43″, it is general to change the resistance value of the resistor element during the step of manufacturing the DA converter circuit 43″ (for example, in changing the wiring). Here, with the change of the property of the liquid crystal display panel, also the first voltage range (the voltage range in which the optical transmittance of the liquid crystal display panel changes nonlinearly and gently relative to the change of the gray scale voltage) and the second voltage range (the voltage range in which the optical transmittance of the liquid crystal display panel changes linearly and steeply relative to the change of the gray scale voltage) change, so that the number of ideal gray scale voltages within the first voltage range changes. For example, it is supposed that, in Embodiment 1, gray scale voltages V₀ to V₅ and V₅₄ to V₆₃ within the first voltage range change to gray scale voltages V₀ to V₇ and V₅₂ to V₆₃ due to the change of the property of the liquid crystal display panel. At this time, the reference voltage generator circuit 431 generates reference voltages V₇ and V₅₃, and the selector circuit 432 has to output the reference voltage V₇ or V₅₃ to the input terminals IN1 and IN2 of the voltage follower circuit 433 in case where a gray scale value “7”or “53” is inputted. However, in Embodiment 1, the reference voltage V₇ or V₅₃ is not generated, and even if the reference voltage generator circuit 431 generates the reference voltage V₇ or V₅₃, the selector circuit 432 does not include a switch pair for selecting the reference voltage V₇ or V₅₃ and for outputting the thus selected reference voltage to the voltage follower circuit 433. Further, a transistor constituting the switch pair cannot be added during and after the aforementioned step, so that the DA converter circuit 43 of Embodiment 1 cannot cover the change of the property of the liquid crystal display panel.

Here, in order to cover the change of the property of the liquid crystal display panel, the DA converter circuit 43″ according to the present embodiment causes the reference voltage generator circuit 431′ to generate preliminary reference voltages V₇ and V₅₃ as described above. Further, the selector circuit 432″ includes a preliminary switch pair SWD for selecting each of the additionally generated reference voltages V₇ and V₅₃ as a reference voltage to be outputted to the voltage follower circuit 433 in case where the number of reference voltages generated by the reference voltage generator circuit 431 increases with the change of the property of the liquid crystal display panel.

Thus, the DA converter circuit 43″ according to the present embodiment can cover the change of the property of the liquid crystal display panel.

Note that, in the present embodiment, four switch pairs SWD are provided as the preliminary switch pairs, but the number of the preliminary switch pairs may be suitably changed according to the number of reference voltages generated by the reference voltage generator circuit 431″.

Moreover, the DA converter circuit according to the present embodiment is preferably arranged such that: the selecting section selects one reference voltage if a gray scale value corresponding to a gray scale voltage in any one of the end portions is inputted; and the selecting section selects one or two reference voltages if a gray scale value corresponding to a gray scale voltage in the center portion is inputted.

In this configuration, the selecting section selects one reference voltage if a gray scale value corresponding to a gray scale voltage in any one of the end portions is inputted. Accordingly, from the selecting section, the output section receives one reference voltage corresponding to the inputted gray scale value, for the first voltage range. As a result, the output section outputs the inputted reference voltage to the liquid crystal display panel for the first voltage range. By this, for the first voltage range, the reference voltage generated by the generating section can be outputted from the output section, as described above. Thus, it is possible to output a gray scale voltage to the liquid crystal display panel without deviating from the ideal gray scale voltage, for the first voltage range.

Moreover, for the second voltage range, the selecting section of the DA converter circuit according to the present embodiment selects one or two reference voltages from m reference voltages. By this, the selecting section of the DA converter circuit according to the present embodiment has a simpler circuit configuration than a conventional selecting section in which one reference voltage is selected from n reference voltages, because the selecting section of the DA converter circuit according to the present embodiment has fewer reference voltages from which it should select one or two reference voltages. As a result, the DA converter circuit with the selecting section can be smaller in chip size, thereby reducing the chip size for the liquid crystal driver circuit provided with the DA converter circuit.

Furthermore, the DA converter circuit according to the present embodiment is preferably configured such that the generating section includes j resistor elements connected in series, where j is a natural number not less than m−1, but less than n−1; and the m reference voltages are outputted from the j resistor elements respectively.

With this configuration, the generating section divides the input voltage by using the j resistor elements connected in series, so as to generate the m reference voltages.

Therefore, if j=m−1, the m reference voltages are outputted by using all the resistor elements, while if j≧m, the generating sections has one or more resistor elements from which no reference voltage is outputted.

If the specification of the liquid crystal display panel is altered, there is a case where only ideal voltage values for the gray scale voltages are changed while the number of the gray scales of the gray scale value to be inputted in the DA converter circuit and the number of the gray scales of the gray scale voltage to be outputted from the DA converter circuit is not changed. In this case, the generating section of the DA converter circuit is modified such that the ratio of the resistive division by using the resistor elements is changed. In other words, this allows the first voltage range to change, and consequently changes the number of the gray scale voltages corresponding to the first voltage range.

The change in the number of the gray scale voltages for the first voltage range can be carried out by using the resistor element which has not been used to output the reference voltage, in other words, by using the spare resistor element. More specifically, an increase in the number of the gray scale voltages for the first voltage range can be carried out by adjusting the resistor elements of the generating section in terms of their resistances so as to output the newly added gray scale voltage from a spare resistor element.

Moreover, the DA converter circuit according to the present embodiment is preferably configured such that: the selecting section includes: switching elements for respectively switching over connection of the output section between the resistor elements; and spare switching elements spared for a case where the number of the reference voltages outputted from the generating section for each end portion respectively is increased, the spare switching elements for respectively switching over connection of the output section between that resistor elements which respectively output reference voltages newly added by the increase of the number of the reference voltages.

With this configuration, the selecting section can connect the output section with a terminal of the resistor element from which the newly added reference voltage is outputted, via the spare switching element in case the number of the reference voltages to be generated by the generating section is increased for the first voltage range according to the specification change in the liquid crystal display panel as described above. That is, the selecting section can select one reference voltage for the newly added reference voltage and output the selected reference voltage to the output section. By this, the newly added reference voltage for the first voltage range can be outputted as the gray scale voltage, from the output section. As a result, even after the specification of the liquid crystal display panel is altered, the DA converter circuit according to the present invention can output the gray scale voltage in such a way that the specification of the liquid crystal display panel is fully reflected.

The present invention is not limited to the description of the embodiments above, but may be altered by a skilled person within the scope of the claims. An embodiment based on a proper combination of technical means disclosed in different embodiments is encompassed in the technical scope of the present invention.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

The driver circuit for display, according to the present invention and a method for designing the driver circuit may be configured as below.

### (First Configuration)

A driver circuit for gray scale display, including a circuit for generating gray scale voltages, an output circuit for outputting a voltage that is an average of two or more of the gray scale voltages inputted thereto, a selector circuit having a first condition in which the selector circuit supplies to the output circuit the gray scale voltages as such, and a second condition in which the selector circuit supplies to the output circuit gray scale voltages different from the gray scale voltages, wherein the selector circuit operates only in the first condition for an upper portion and lower portion of a range of the gray scale voltages while the selector circuit operates in the first and second conditions for a center portion of the range of the gray scale voltages.

### (Second Configuration)

The driver circuit as set forth in the first configuration, comprising a switching element for enabling that portion of the selector circuit which operates in the first condition, to operate in the second condition.

### (Third Configuration)

The driver circuit as set forth in the first configuration, comprising a switching element for enabling that portion of the selector circuit which operates in the second condition, to operate in the first condition.

### (Fourth Configuration)

The driver circuit as set forth in any one of the first to third configurations, comprising a spare reference voltage so as to enable that portion of the selector circuit which operates in the first condition, to operate in the second condition.

### (Fifth Configuration)

The driver circuit as set forth in the second or third configuration, wherein the switching element is capable of changing the conditions of the selector circuit for the upper and lower portion of the range of the gray scale voltage.

### (Sixth Configuration)

The driver circuit as set forth in the fourth configuration wherein the spare reference voltage is capable of changing the conditions of the selector circuit for the upper and lower portion of the range of the gray scale voltage.

### (Seventh Configuration)

A method for designing a driver circuit for gray scale display, including a circuit for generating gray scale voltages, an output circuit for outputting a voltage that is an average of two or more of the gray scale voltages inputted thereto, a selector circuit having a first condition in which the selector circuit supplies to the output circuit the gray scale voltages as such, and a second condition in which the selector circuit supplies to the output circuit gray scale voltages different from the gray scale voltages, wherein the selector circuit operates only in the first condition for an upper portion and lower portion of a range of the gray scale voltages while the selector circuit operates in the first and second conditions for a center portion of the range of the gray scale voltages, the method comprising: forming first circuits each including a selector circuit in the first condition and a selector circuit in the second condition; calculating a voltage to be outputted from the output circuit in case where the first circuit is operated; comparing the calculated voltage with a predetermined voltage, so as to obtain a voltage difference therebetween; and forming a second circuit by converting a first circuit such that the selector circuit operating in the second condition is converted to operate in the first condition.

### INDUSTRIAL APPLICABILITY

The present invention provides a DA converter circuit configured to output a gray scale voltage to a liquid crystal display panel, wherein the gray scale voltage is generated from reference voltages fewer than gray scales of the liquid crystal display panel, and still to be able to prevent deterioration in display quality of the liquid crystal display panel. Especially, the present invention is applicable to liquid crystal display apparatus of multi gray scales.

### REFERENCE SINGS LIST

10 Liquid crystal display apparatus
20 Liquid crystal display panel
40 Source bus line driver circuit (liquid crystal driver circuit)
43 DA converter circuit
43′ DA converter circuit
43″ DA converter circuit
431 Reference voltage generator circuit (generating section)
431′ Reference voltage generator circuit (generating section)
431″ Reference voltage generator circuit (generating section)
432 Selector circuit (selecting section)
432′ Selector circuit (selecting section)
432″ Selector circuit (selecting section)
433 Voltage follower circuit (output section)
433′ Voltage follower circuit (output section)
SW Switch pair (switching element)
SWA Switch pair (switching element)
SWB Switch pair (switching element)
SWC Switch pair (switching element)
SWD Switch pair (spare switching element)

1. A DA converter circuit for outputting a gray scale voltage to a liquid crystal display panel in accordance with a gray scale value externally inputted to the DA converter circuit, where the gray scale voltage and the gray scale value are of n gray scales and n is a natural number of 2 or more, the DA converter circuit comprising:
a generating section for generating m reference voltages, which are different from each other, where m is a natural number less than n;
a selecting section for selecting one or two reference voltages from the m reference voltages in according to the inputted gray scale value; and
an output section for outputting the gray scale voltage that is the one reference voltage thus selected or a mean value of the two reference voltages thus selected,
the generating section generating the reference voltages in such a manner that, respectively for each end portion of a voltage range of the gray scale voltages of n gray scales, the generating section generates i reference voltages, where i is a natural number less than m and is as many as a variety of gray scale voltages that the output section is capable of outputting for each end portion respectively, and for a center portion of the voltage range, the generating section generates m−i reference voltages.

2. The DA converter circuit as set forth in claim 1, wherein:
the selecting section selects one reference voltage if a gray scale value corresponding to a gray scale voltage in any one of the end portions is inputted; and
the selecting section selects one or two reference voltages if a gray scale value corresponding to a gray scale voltage in the center portion is inputted.

3. The DA converter circuit as set forth in claim 1, wherein:
the generating section includes j resistor elements connected in series, where j is a natural number not less than m−1, but less than n−1; and
the m reference voltages are outputted from the j resistor elements respectively.

4. The DA converter circuit as set forth in claim 3, wherein:
the selecting section includes:
switching elements for respectively switching over connection of the output section between the resistor elements; and
spare switching elements spared for a case where the number of the reference voltages outputted from the generating section for each end portion respectively is increased, the spare switching elements for respectively switching over connection of the output section between that resistor elements which respectively output reference voltages newly added by the increase of the number of the reference voltages.

5. A liquid crystal driver circuit for driving a liquid crystal display panel, the liquid crystal driver circuit comprising:
a DA converter circuit for outputting a gray scale voltage to the liquid crystal display panel in accordance with a gray scale value externally inputted to the DA converter circuit, where the gray scale voltage and the gray scale value are of n gray scales and n is a natural number of 2 or more,
the DA converter circuit including:
a generating section for generating m reference voltages, which are different from each other, where m is a natural number less than n;
a selecting section for selecting one or two reference voltages from the m reference voltages in according to the inputted gray scale value; and
an output section for outputting the gray scale voltage that is the one reference voltage thus selected or a mean value of the two reference voltages thus selected,
the generating section generating the reference voltages in such a manner that, respectively for each end portion of a voltage range of the gray scale voltages of n gray scales, the generating section generates i reference voltages, where i is a natural number less than m and is as many as a variety of gray scale voltages that the output section is capable of outputting for each end portion respectively, and for a center portion of the voltage range, the generating section generates m−i reference voltages.

6. A liquid crystal display apparatus comprising a liquid crystal display panel and a liquid crystal driver circuit for driving the liquid crystal display panel,
the liquid crystal driver circuit including:
a DA converter circuit for outputting a gray scale voltage to a liquid crystal display panel in accordance with a gray scale value externally inputted to the DA converter circuit, where the gray scale voltage and the gray scale value are of n gray scales and n is a natural number of 2 or more, the DA converter circuit including:
a generating section for generating m reference voltages, which are different from each other, where m is a natural number less than n;
a selecting section for selecting one or two reference voltages from the m reference voltages in according to the inputted gray scale value; and
an output section for outputting the gray scale voltage that is the one reference voltage thus selected or a mean value of the two reference voltages thus selected,
the generating section generating the reference voltages in such a manner that, respectively for each end portion of a voltage range of the gray scale voltages of n gray scales, the generating section generates i reference voltages, where i is a natural number less than m and is as many as a variety of gray scale voltages that the output section is capable of outputting for each end portion respectively, and for a center portion of the voltage range, the generating section generates m−i reference voltages.

7. A method for designing a DA converter circuit for outputting a gray scale voltage to a liquid crystal display panel in accordance with a gray scale value externally inputted to the DA converter circuit, where the gray scale voltage and the gray scale value are of n gray scales and n is a natural number of 2 or more,
the DA converter circuit including:
a generating section for generating m reference voltages, which are different from each other, where m is a natural number less than n;
a selecting section for selecting one or two reference voltages from the m reference voltages in according to the inputted gray scale value; and
an output section for outputting the gray scale voltage that is the one reference voltage thus selected or a mean value of the two reference voltages thus selected,
the generating section generating the reference voltages in such a manner that, respectively for each end portion of a voltage range of the gray scale voltages of n gray scales, the generating section generates i reference voltages, where i is a natural number less than m and is as many as a variety of gray scale voltages that the output section is capable of outputting for each end portion respectively, and for a center portion of the voltage range, the generating section generates m−i reference voltages,
the method comprising:
a first calculating step for calculating the gray scale voltage to be outputted from the output section, which gray scale voltage is the one reference voltage thus selected or the mean value of the two reference voltages thus selected;
a second calculating step for calculating a difference between the mean value thus calculated and an ideal gray scale voltage value for a gray scale value corresponding to the mean value, the ideal gray scale voltage value being obtained in advance; and
a voltage range determining step for determining the end portions and center portion of the voltage range according to the voltage difference thus calculated.
